(19) United States
(12) Patent Application Publication
(10) Pub. No.: US 2026/0287788 A1
(43) Pub. Date: Sep. 24, 2026

(54) Silicon Carbide Crystalline Material

(71) Applicant: Wolfspeed, Inc., Durham, NC (US)

(72) Inventors: Robert Leonard, Raleigh, NC (US); Simon Bubel, Carrboro, NC (US); Yuri I. Khlebnikov, Raleigh, NC (US); Elif Balkas, Cary, NC (US); Kathy Doverspike, Cary, NC (US); Michael Anthony Fusco, Wake Forest, NC (US); Adrian Roger Powell, Cary, NC (US); Robert Conner Glass, Chapel Hill, NC (US); Valeri Fedorovich Tsvetkov, Durham, NC (US); Varad Rajan Sakhalkar, Cary, NC (US); Eugene Deyneka, Cary, NC (US); Jong Hyup Lee, Cary, NC (US); Caleb Andrew Kent, Durham, NC (US); Julio Garceran, Cary, NC (US)

(21) Appl. No.: 19/310,415

(22) Filed: Aug. 26, 2025

Related U.S. Application Data
(60) Provisional application No. 63/776,664, filed on Mar. 24, 2025.
(60) Provisional application No. 63/818,981, filed on Jun. 6, 2025.

(51) Int. Cl. G02B 1/02; C30B 29/36; G02B 5/00; G02B 27/01

(52) U.S. Cl. CPC G02B 1/02; C30B 29/36; G02B 5/003; G02B 27/0172; G02B 2027/0178

(57) ABSTRACT

Example structures and methods for producing structures having a silicon carbide crystalline material are provided. In one example, a structure includes a silicon carbide crystalline material. The silicon carbide crystalline material exhibits a change in an optical property when illuminated with polarized light along an axis generally perpendicular to a c-axis of the crystalline material. A thickness of the structure is at least about 10 mm.

### PRIORITY CLAIM

The present application claims the benefit of priority of U.S. Provisional Application Ser. No. 63/776,664 filed on Mar. 24, 2025, which is incorporated herein be reference. The present application claims the benefit of priority of U.S. Provisional Application Ser. No. 63/818,981 filed on Jun. 6, 2025, which is incorporated herein by reference.

### FIELD

The present disclosure relates generally to crystalline materials, such as silicon carbide crystalline materials.

### BACKGROUND

Silicon carbide exhibits many attractive electrical and thermophysical properties. Silicon carbide is especially useful due to its physical strength and high resistance to chemical attack as well as various electronic properties, including radiation hardness, high breakdown field, a wide bandgap, high saturated electron drift velocity, high temperature operation, and absorption and emission of high energy photons in the blue, violet, and ultraviolet regions of the spectrum. Compared with other semiconductor materials, including silicon and sapphire, such properties of silicon carbide make it more suitable for the fabrication of wafers for high power density solid state devices, including power electronic, radio frequency, and optoelectrical devices.

Continuous development has led to a level of maturity in the fabrication of silicon carbide workpiece (e.g., wafers) that allows such semiconductor devices to be manufactured for increasingly widespread commercial applications. As the semiconductor device industry continues to mature, continued improvement of silicon carbide wafer characteristics may be desirable to meet challenging demands of semiconductor devices and applications.

Silicon carbide crystalline materials may also be useful as components or structures beyond semiconductor devices. For instance, with its high index of refraction (e.g., index of refraction of 2.6), increased acceptance angle of incoming light, and increased field of view at the output, silicon carbide has been found to be useful as waveguides for augmented reality and/or virtual reality applications (e.g., near-eye displays). U.S. Pat. No. 12,024,794 discloses silicon carbide material with reduced optical absorption in the visual spectrum. Improved silicon carbide crystalline materials, workpieces, wafers, and related devices for optical applications, including virtual reality and augmented reality applications, windows for challenging environments, and/or other devices and applications taking advantage of the properties of silicon carbide.

### SUMMARY

Aspects and advantages of embodiments of the present disclosure will be set forth in part in the following description, or can be learned from the description, or can be learned through practice of the embodiments.

One example aspect of the present disclosure is directed to a structure comprising a silicon carbide crystalline material. The silicon carbide crystalline material exhibits a change in an optical property when illuminated with polarized light along an axis generally perpendicular to a c-axis of the crystalline material. A thickness of the structure is at least about 10 mm.

In an aspect, the present disclosure provides an example structure. In some implementations, the example structure includes a first absorption coefficient that is less than about 0.15 reciprocal centimeters (cm⁻¹) over a wavelength range from 420 nanometers (nm) to 700 nm along a c-axis of the crystalline material. In some implementations, the silicon carbide crystalline material exhibits a change in a second absorption coefficient along an axis generally perpendicular to the c-axis when illuminated with polarized light along the axis generally perpendicular to the c-axis.

In an aspect, the present disclosure provides an example structure. The structure includes a silicon carbide crystalline material. The structure has a first absorption coefficient less than about 0.15 cm⁻¹ over a wavelength range from about 420 nm to about 700 nm along a c-axis of the crystalline material. The structure has a second absorption coefficient that is defined by a minimum value and a maximum value that are 0.15 cm⁻¹ apart over a wavelength range from about 420 nm to about 700 nm along a second axis generally perpendicular to the c-axis of the crystalline material. The structure has a thickness along the c-axis in a range of about 10 mm to about 200 mm.

In an aspect, the present disclosure provides a method of producing a silicon carbide structure. The method includes providing a silicon carbide crystalline material structure comprising a c-axis. The method includes measuring a change in at least one optical property of the crystalline material when illuminating the crystalline material with polarized light along an axis generally perpendicular to the c-axis. The method includes processing the silicon carbide crystalline material structure based at least in part on the change in the at least one optical property.

In an aspect, the present disclosure provides a method of producing a silicon carbide structure. The method includes providing a silicon carbide crystalline material structure comprising a c-axis. The method includes measuring a first optical property along a first axis through the crystalline material and measuring a second optical property along a second axis through the crystalline material, wherein the first axis is different from the second axis. The method includes processing the silicon carbide crystalline material structure based at least in part on the first optical property and the second optical property.

In an aspect, the present disclosure provides an optical device. The optical device includes a waveguide of crystalline material, the crystalline material comprising silicon carbide. The optical device includes a first input coupler on the waveguide, the first input coupler configured to input light for output as a first visual display. The optical device includes a second input coupler on the waveguide, the second input coupler configured to input light for output as a second visual display. The second visual display is spatially separated from the first visual display.

In an aspect, the present disclosure provides an optical device. The optical device includes a waveguide of crystalline material, the crystalline material comprising silicon carbide. The optical device includes a coupler on the waveguide. The coupler is a structure defined in the silicon carbide crystalline material (e.g., laser-defined structure).

In an aspect, the present disclosure provides an optical device. The optical device includes a first waveguide comprising silicon carbide crystalline material. The optical device includes a second waveguide comprising silicon carbide crystalline material. At least a portion of the first waveguide is generally parallel to the second waveguide. The first waveguide comprises an output coupler configured to output light to be transmitted through the second waveguide.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a first perspective view crystal plane diagram showing the coordinate system for a hexagonal crystal according to example aspects of the present disclosure;

FIGS. 2A, 2B, and 2C depict a top-down view and a side view of example silicon carbide crystalline material structures according to example aspects of the present disclosure;

FIG. 3 depicts a cross-sectional view of a silicon carbide crystalline material structure according to example aspects of the present disclosure;

FIGS. 4A-4B depict a change in electromagnetic radiation absorption characteristics associated with silicon carbide crystalline material structures according to example aspects of the present disclosure;

FIGS. 5A-5B depict cross-sectional views of silicon carbide crystalline material structures according to example aspects of the present disclosure;

FIG. 6 depicts a method for processing a silicon carbide crystalline material structure according to example aspects of the present disclosure;

FIGS. 7A, 7B, 7C, 7D, 7E, 7F, 7G, 7H, 7I, 7J, and 7K depict silicon carbide crystalline material structures according to example aspects of the present disclosure;

FIGS. 8A, 8B, 8C, 8D, 8E, 8F, 8G, 8H, 8I, 8J, and 8K depict formation of optical devices from silicon carbide crystalline material structures according to example aspects of the present disclosure;

FIGS. 9A, 9B, and 9C depict example silicon carbide crystalline material structures according to example aspects of the present disclosure;

FIGS. 10A, 10B, 10C, 10D, 10E, 10F, and 10G depict example multipiece crystalline material structures according to example aspects of the present disclosure;

FIG. 11 depicts an example device formed using a silicon carbide crystalline material structure according to example aspects of the present disclosure;

FIG. 12 depicts a block diagram of a method according to example aspects of the present disclosure;

FIG. 13 depicts a block diagram of a method according to example aspects of the present disclosure;

FIG. 14 depicts an optical device according to example aspects of the present disclosure;

FIGS. 15A, 15B, 15C, and 15D depict cross-sectional views of example optical devices according to example embodiments of the present disclosure;

FIGS. 16A, 16B, 16C, and 16D depict cross-sectional views of example optical devices according to example embodiments of the present disclosure;

FIGS. 17A and 17B depict cross-sectional views of example optical devices according to example embodiments of the present disclosure;

FIG. 18 depicts a cross-sectional view of an example optical device according to example embodiments of the present disclosure;

FIG. 19 depicts a cross-sectional view of an example optical device according to example embodiments of the present disclosure.

FIG. 20 depicts a cross-sectional view of an example optical device according to example embodiments of the present disclosure.

Repeat use of reference characters in the present specification and drawings is intended to represent the same and/or analogous features or elements of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

While silicon carbide exhibits superior material properties, crystal growth techniques used to grow silicon carbide are very different and significantly more challenging than growth processes for other crystalline materials. Certain crystalline materials utilized in semiconductor manufacturing, such as silicon and sapphire, have significantly lower melting points, allowing for direct crystal growth techniques from melted source materials that provide for fabrication of large diameter crystalline materials (e.g., 300 mm in diameter). In contrast, bulk crystalline silicon carbide is often produced by a seeded sublimation growth process at high temperatures (e.g., greater than 1800° C., such as greater than 2000° C.) where various challenges include impurity incorporation, structural defects associated with thermal and crystallographic stress, and formation of different polytypes, among others.

In a typical silicon carbide growth technique, a substrate and a source material are both placed inside of a reaction crucible. A thermal gradient created when the crucible is heated encourages vapor phase movement (e.g., vapor transport) of the materials from the source material to the substrate followed by condensation upon the substrate and resulting bulk crystal growth. Impurities can be introduced as dopants into silicon carbide during crystal growth and these dopants can regulate certain properties. For sublimation growth of silicon carbide, a dopant can be introduced into the chamber in a variety of manners so that the dopant will be present in the bulk silicon carbide crystal produced from that process. The process is controlled to provide an appropriate concentration of the dopant for a particular application. Following solid bulk crystal growth, individual wafers of silicon carbide may be obtained by slicing a bulk crystal ingot or boule of silicon carbide, and the individual wafers may subsequently be subjected to additional processes, such as grinding, lapping, polishing, etc.

In some cases, silicon carbide crystalline material structures may be provided with reduced optical absorption. In certain aspects, silicon carbide crystalline material structures may have reduced absorption coefficients for wavelengths of light within the visible light spectrum. Various peaks in absorption over a wavelength spectrum may be reduced in silicon carbide crystalline materials to improve absorption coefficient uniformity across, for example, the visible light spectrum. By providing such improvements in absorption coefficients for silicon carbide crystalline materials, reduced reflection and transmission losses of light in corresponding optoelectrical devices and/or optical components may be realized. Example techniques for producing silicon carbide crystalline material structures with reduced absorption coefficients for wavelengths of light in the visible spectrum are provided in U.S. Pat. No. 12,024,794, titled “Reduced optical absorption for silicon carbide crystalline materials” filed on Jun. 17, 2021, which is incorporated herein by reference for all purposes.

For instance, crystalline material structures with reduced absorption coefficients may be produced, for instance, at least in part using a thermal conditioning process. The thermal conditioning process may comprise annealing the structure at a temperature in a range from about 1300° C. to about 2600° C., such as in a range from about 2000° C. to about 2600° C. In certain embodiments, after annealing, the thermal conditioning process comprises cooling the structure down from the temperature at a rate in a range from about 0.5° C. to about 5° C. per minute. In certain embodiments, the annealing temperature is in a range from about 1300° C. to about 2000° C. In certain embodiments, the thermal conditioning process comprises cooling the crystalline material structure down from the temperature at a rate in a range from above about 5° C. to about 100° C. per minute.

In some examples, silicon carbide may be used as an optical material for optical devices, optoelectrical devices, or other devices (e.g., semiconductor devices) due to optical properties related to the material, high purity, high index of refraction, high thermal conductivity, durability, hardness, radiation hardness, birefringence and anisotropic absorption properties, etc. Silicon carbide may also be useful when doped to control absorption properties in the near UV, visible and near IR wavelengths, especially in the blue wavelengths where the absorption is typically highest.

Aspects of the present disclosure are directed to structures including crystalline material silicon carbide (e.g., 4H—SiC, 6H—SiC) with controlled doping, defects, optical properties, and/or demarcated orientation that may be used to fabricate other downstream devices, such as optical devices, optoelectrical devices, electronic devices, etc. The structure may be a silicon carbide workpiece, semiconductor wafer, boule, ingot, or preform.

As used herein, a “silicon carbide workpiece” is any structure comprising silicon carbide that is subjected to one or more fabrication processes. As used herein, a “preform” of crystalline material refers to a structured body of the material, typically in an intermediate shape or form, that is designed for further processing, such as machining, shaping, or growth into a final optical, electronic, or structural component. The preform may be fabricated through methods such as controlled crystal growth and can serve as a precursor for other components, such as optical devices, electronic devices, or other components.

In some aspects, a silicon carbide crystalline material structure may be used in the fabrication of custom devices (e.g., optical devices, optoelectrical devices, electrical devices), substrates, or other devices without dependence on initial structure shape, orientation or surface processing, while still retaining the ability to measure the specified property of the silicon carbide material, such as optical properties, resistivity, reduced visible defects within the material, or other properties.

Aspects of the present disclosure are discussed with reference to fabrication of optical devices for purposes of illustration and discussion. However, aspects of the present disclosure are applicable to the fabrication of other types of devices (e.g., semiconductor-based electronic devices, piezoelectric devices, devices operating based on optical properties, devices used to determine quantum states (e.g., for quantum computing), or other devices.

As used herein, “optical properties” may include absorption properties, transmittance properties, reflectance properties, refractive index, dispersion, polarization, birefringence, opacity, scattering, fluorescence, phosphorescence, piezoelectric characteristics (e.g., and piezoelectric effect on electromagnetic radiation), luminescence, photoluminescence (e.g., photoluminescent response to detect vacancies), non-linear optical characteristics, temperature dependent optical characteristics (e.g., temperature dependent absorption loss), deformation effects responsive to exposure to electromagnetic radiation, laser induced damage thresholds (LIDT), defects (e.g., polytype transitions and/or inclusions, dislocations with respect to crystallographic orientation, such as threading edge dislocations, screw dislocations, micropipes, basal plane dislocations, etc.) and their effects on optical characteristics, such as impact on absorption properties, etc. One example optical property may be an absorption coefficient. An absorption coefficient may indicate how a material absorbs energy (e.g., electromagnetic radiation) per unit distance at specified wavelengths. Aspects of the present disclosure are discussed with reference to absorption coefficients. However, the present disclosure is not limited to absorption coefficient but may be applicable, in some cases, to any optical property.

Optical properties are not limited to the visible light spectrum of electromagnetic radiation. Optical properties can be indicative of properties for wavelengths across the electromagnetic spectrum, such as the visible light spectrum (e.g., about 380 nm to about 700 nm), the infrared spectrum (e.g., 700 nm to about 1 mm), the ultraviolet spectrum (e.g., about 10 nm to about 400 nm), or other suitable wavelength range in the electromagnetic spectrum.

In some embodiments, the silicon carbide crystalline material structure may be processed for controlling optical properties or other properties (e.g., resistivity) through the material. In some embodiments, optical properties may be measured (e.g., using one or more spectrophotometers, refractometers, polarimeters, ellipsometers, interferometers, goniometers, photometers, colorimeters, fluorescence spectrometers, scatterometers, radiometers or other suitable device) across multiple different axes, surfaces, crystal planes (e.g., c-plane, a-plane, m-plane), off-axis planes, between crystal planes, and/or directions through the silicon carbide crystalline material structure. The measurement and/or correlation of these measurements of optical properties may be used for further processing of the structure, such as for characterization, determining where to cut or remove material from structures (e.g., optical devices, optoelectrical devices, electronic devices, or other devices) from the structure, evaluation, quality control, sorting into categories or bins, or other processing of the structure.

Standard sized crystalline material structures may not meet the specified needs of a customer or downstream user. For instance, the surface may not be polished as needed. The structure may have the wrong thickness tolerances. The overall shape of the structure may not be useful. The customer may want to cut at oblique orientations to the original shape of the structure to improve properties of their optical or device elements. A silicon carbide crystalline material structure, according to examples of the present disclosure, may solve these problems by providing a structure with desired optical properties or other characteristics and allowing the customers to process the material as desired.

In some cases, material properties may vary with respect to the axis (e.g., c-axis or other axis) of the crystalline material structure, resulting in devices of different properties manufactured in the structure. Measuring optical properties through one axis of a thick structure (e.g., a structure greater than about 10 mm in thickness, such as between about 10 mm thick and about 200 mm thick), may insufficiently evaluate the yield or material properties of the manufactured devices, such as optical devices. For instance, measurements perpendicular only to the c-axis of the crystalline material may be difficult to correlate to the finished device due to a shape of the crystalline material structure, surface parameters affecting a measurement (e.g., roughness, topographical features, reflection, etc.), and limitations of measurement tools. Combining the ability to measure along multiple axes (e.g., both c-axis and generally perpendicular to c-axis) allows for characterization of the crystalline material structure so that the distribution of a property (e.g., an optical property such as absorption coefficient) is known down, for instance, a central axis or a longest dimension of the structure, an axis generally perpendicular to the central axis of the structure, through another axis of the structure, along a surface of the structure, and/or along a desired crystal plane or off-axis plane of the structure. In some embodiments, the distribution of a property (e.g., an optical property) may be mapped across an entire volume or at least a portion of the volume of the structure from multiple directions or angles.

In some examples, measuring optical properties may allow for characterization of defects and their effects on optical properties from different directions. Defects associated with dislocations (e.g., threading edge dislocations, screw dislocations, micropipes, basal plane dislocations, etc.) may scatter or absorb light transmitting through the crystalline material. Defects have been detected, such as dislocation defects have been detected using, for instance, x-ray topography, etching techniques and other imaging techniques. However, according to aspects of the present disclosure, defects can be detected or analyzed by looking at different optical response to light transmitted through the defect, such as different absorption and/or scattering.

In some cases, a surface of the crystalline material structure (e.g., a silicon carbide crystalline material structure) may be measured with eddy current or radiofrequency (RF) resistivity techniques to determine the surface conductivity or resistivity. This may provide an indication of optical and electrical properties of the crystal down the length of the structure, as well as on the surface(s) of the structure. However, these measurement techniques may not provide insight into interior defects, insufficiencies, or other variations of material properties within the crystalline material of the structure. Actively grinding/polishing at least a portion of the structure may allow non-destructive measurement techniques to be utilized to determine material properties or variations in the crystal lattice within the structure. For instance, visibility or conspicuity to electromagnetic radiation or anomalies caused by defects within the crystal lattice of the structure may be useful to detect regions that meet specifications or are to be rejected. Defects may also be detected by change in resonance from vibrational energy, (e.g., acoustic, ultrasound, or other methods).

Polishing (e.g., chemical mechanical polishing (CMP)) nominally parallel windows on at least a portion of one or more surfaces of the structure allows for measurement of optical properties or other properties through the crystalline material for instance, by measuring the transmittance through the structure and/or reflectivity of the surface. For thicker structures, transmittance may inversely correlate with absorbance.

In some cases, the structure may also be combined (e.g., glued, welded, adhered, coupled, or otherwise bonded) with other structure materials placed together to maximize or enhance the anisotropic, optical, electrical, mechanical, and/or thermal behavior of silicon carbide. For example, one structure (e.g., preform) may be bonded at a 90° angle relative to another structure (e.g., preform) to fabricate an optical device.

In some cases, capitalizing on enhanced nitrogen impurity detection with polarized light perpendicular to the c-axis (Biederman effect), subtle differences in the distribution of nitrogen (e.g., n-type dopants) or other suitable dopants may be determined by visual detection techniques either by eye, with a photodetector (e.g., spectrophotometer), such as with relative color grading with representative color gauges.

By using one or more of these techniques, a structure may be characterized to ensure specified material properties are met. Statistical use of these techniques may allow the ability to rely on the relevant measurement along one axis to infer characteristics along another axis (e.g., using a machine learning model). For example, instead of measuring both the c-axis absorption and the absorption along an axis generally perpendicular to the c-axis, learning may occur that allows for dependence on the measurement perpendicular to the c-axis to infer the absorption through the structure along the c-axis.

Some methods for silicon carbide crystalline material manufacture and distribution provide for structures with a specific wafer/substrate form parallel (e.g., or off-axis to the c-axis of the substrate, such as nominally off-axis or vicinal) with a fixed range of thickness and polishing processes according to optimal semiconductor specifications. However, due to the fixed structure of wafers/substrates, custom applications may result in egregious waste of materials or complete impossibility of manufacture. Additionally, certain methods of manufacture do not identify dopant concentration and distribution across a substrate given the predefined manufacturing specifications of semiconductor specifications.

Accordingly, example aspects of the present disclosure are directed to systems and methods for manufacturing crystalline material structures, or preforms, with a large thickness and/or width. In some cases, the Biederman effect may be used identify and label distributions of optical properties across a structure. For instance, as an example, the present disclosure may provide for a crystalline material structure with a thickness of at least 10 mm and exhibiting a change in an optical property when illuminated with polarized light along an axis generally perpendicular to a c-axis of the crystalline material. The polarized light may be linearly polarized light with a polarization direction that is generally perpendicular or generally parallel to the c-axis.

Crystalline material structures in accordance with the present disclosure may exhibit a variety of optical properties. For instance, in some embodiments, at least a portion of the structure may include an absorption coefficient along a c-axis of the crystalline material that is less than about 0.15 cm⁻¹ over a wavelength range from about 420 nm to about 700 nm. Alternatively, in some embodiments, at least a portion of the crystalline material may exhibit a notch absorption coefficient along a c-axis in a range within the wavelength range from about 420 nm to about 700 nm. The notch absorption coefficient may include one or more spikes of absorption coefficient at one or more different wavelength ranges across the electromagnetic spectrum (e.g., at blue light or about 400 nm to about 500 nm, yellow light or about 570 nm to about 590 nm, or other subset of wavelength ranges). A notch absorption coefficient refers to an absorption coefficient for a subset of the wavelength range from about 420 nm to about 700 nm that is at least 15% greater than the absorption coefficient for the remainder of the wavelength range from about 420 nm to about 700 nm. Crystalline material structures with a notch absorption coefficient may be used, for instance, to provide an optical filter, such as a notch filter, a bandpass filter, a low pass filter, a high pass filter, etc.

Aspects of the present disclosure are discussed with reference to a structure having one or more optical properties, such as absorption coefficients within a set range. A structure includes the specified optical property when at least a portion of the structure exhibits the stated optical property. For instance, a first portion of the structure may exhibit the optical property (e.g., an absorption coefficient along a c-axis of the crystalline material that is less than about 0.15 cm⁻¹ over a wavelength range from about 420 nm to about 700 nm). However, a second portion of the structure may not exhibit the optical property (e.g., may not have an absorption coefficient along a c-axis of the crystalline material that is less than about 0.15 cm⁻¹ over a wavelength range from about 420 nm to about 700 nm). The structure can still be determined to have the optical property when only a portion of the structure exhibits the optical property.

In some embodiments, the crystalline material structure may exhibit different optical properties across different axes, surfaces, crystal planes, off-axis planes, or regions, particularly when exposed to polarized light. For instance, at least a first region of the structure may exhibit an increase in the absorption coefficient in a wavelength range from about 450 nm to about 495 nm, and a second region or along a second axis may not exhibit the same increase when exposed to polarized light. As another example, at least a first region of the structure may exhibit an increase in the absorption coefficient in a wavelength range from about 570 nm to about 590 nm and a second region, or along a second axis may not exhibit the same increase. Stated differently, the structure may contain a first region which exhibits an increase in its absorption coefficient in a wavelength range between about 450 nm to about 495 nm or between about 570 nm to about 590 nm and a second region which does not exhibit said increase. In some instances, the second region may exhibit an increase in absorption coefficient for a wavelength range different than that associated with the first region.

In some embodiments, at least a portion of the crystalline material structure may also include an associated optical uniformity. For instance, the optical properties associated with the structure may be uniform across the structure along an axis that is different from the c-axis (e.g., perpendicular to the c-axis) and may be within a predefined range (e.g., deviate by less than about 10%, such as by less than about 5%, such as by less than about 1%). In some embodiments, an absorption coefficient of the structure along an axis that is different than the c-axis may have a minimum value and a maximum value that are less than or equal to about 0.15 cm⁻¹ apart.

Changes in absorption coefficients in different wavelength ranges may be indicative of various electro-chemical properties and dopant concentrations. For instance, regions of a structure which exhibit an increase in absorption coefficient in a wavelength range between about 450 nm and about 495 nm may include a higher nitrogen dopant concentration (or other suitable dopant) relative to other regions. Additionally, regions which exhibit an increase in absorption coefficient in a wavelength range between about 570 nm and about 590 nm may include a lack of nitrogen dopants and/or a higher p-type dopant (e.g., boron) concentration. Regions which do not exhibit an increase in absorption coefficient may be electrically compensated regions.

The optical properties associated with the crystalline material structure may include transmission, refractive index, and/or reflection properties. For instance, in some embodiments, the crystalline material structure may have a first surface where electromagnetic radiation in a wavelength range between about 380 nm to about 1200 nm enters and a second surface where the electromagnetic radiation exits with a beam divergence of less than about 10°, such as less than about 5°, such as less than about 1°. Similarly, in some embodiments, electromagnetic radiation in a wavelength range between about 420 nm and about 700 nm may enter the first surface and exit the second surface with a beam divergence of less than about 10°, such as less than about 5°, such as less than about 1°. In these embodiments, the first surface and the second surface may be generally parallel. In some embodiments the electromagnetic radiation may enter the first surface and exit the first surface via a reflection in the second surface. Alternatively, in some embodiments, the electromagnetic radiation may enter the first surface, be reflected by a second surface, and exit a third surface. In some embodiments, the surfaces contemplated herein may be curved, non-linear, or linear surfaces.

In some embodiments, the structure may include one or more windows (e.g., polished windows) on at least a portion of one or more surfaces. A surface containing the window may be perpendicular, or generally perpendicular, to a c-plane of the structure or preform. Additionally, or alternatively, the structure or preform may include one or more windows (e.g., polished windows) on at least a portion of the surface such that at least one window includes the c-plane associated with the structure or preform. The window may be characterized by one or more regions on one or more surfaces having a surface roughness in a range of about 0.5 nm to about 100 nm, such as in a range of about 0.5 nm to about 60 nm, such as in a range of about 0.5 nm to about 25 nm.

Aspects of the present disclosure refer to and/or claim a “surface roughness” of a surface. As used herein, unless otherwise specifically noted, the surface roughness is measured as “areal average roughness” Sa. When the present disclosure or claims refer to a surface having a surface roughness being within a range of values, a surface has a surface roughness in the range of values if any 250 micron by 250 micron area on the surface includes a surface roughness Sa within the specified range of values or if any 250 micron by 250 micron area on the surface includes a surface roughness Sz (maximum height) within the specified range of values.

As an example, a surface has a surface roughness in a range of about 0.5 nm to about 180 nm if any 250 micron×250 micron area on the surface has a surface roughness Sa in the range of about 0.5 nm to about 200 nm or if any 250 micron×250 micron area on the surface has a surface roughness Sz in the range of about 0.5 nm to 200 nm. For the sake of clarity, it is not required that the entire surface or region have the surface roughness in the specified range of values. Only a single 250 micron×250 micron area on the surface has to have a surface roughness in the specified range of values (e.g., either Sa or Sz) for the surface to be considered to have a surface roughness in the specified range of values.

Crystalline material structures in accordance with the present disclosure may include various structures and dimensions. In some embodiments, the crystalline material structure may be a cylindrical shape that includes an outer diameter between about 100 mm to about 400 mm, and a thickness along a c-axis associated with the structure between about 10 mm to about 200 mm. Certain aspects of the present disclosure are discussed with reference to cylindrical shapes for purposes of illustration and discussion. However, the crystalline material structure may have any shape or volume, such as prism having a polygonal cross-section (e.g., triangle, square, rectangle, pentagon, hexagon, octagon, rhombus, parallelogram, kite, etc.) or irregular shaped volume, composite shaped volume, etc. A composite shaped volume is a volume that can be classified as a combination of different volume shapes (e.g., prism on cylinder).

Additionally, in some embodiments, the crystalline material may be a preform, workpiece, boule, ingot, or wafer. In some embodiments, the crystalline material may be, may comprise, or may be used to form an optical device, such as a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device. In some embodiments, the crystalline material may be used to form another type of device, such as a semiconductor device, electronic device, optoelectrical device, device window, device affected by optical phenomena, device used to determine quantum states, photonic integrated circuits, etc. The crystalline material need not be restricted to a single structure or multiple structures coupled together. Accordingly, in some embodiments, the crystalline material may include a first structure coupled to a second structure.

Additionally, aspects of the present disclosure are directed to manufacturing a variety of custom preform shapes and sizes with varying dopant concentrations, distributions, surface roughness, and/or optical clarity. As an example, a structure may be processed to have a surface or region with an optical absorption coefficient less than about 0.15 cm⁻¹ using mechanical, radiation, thermal, or doping processes, such as ion implantation, ambient environment exposure, diffusion, or similar processing techniques.

In some embodiments, aspects of the present disclosure may provide for a method of producing a silicon carbide structure including providing the silicon carbide crystalline material, measuring a change in at least one optical property of the crystalline material when illuminating the crystalline material with polarized light along an axis generally perpendicular to the c-axis, and processing the crystalline material based at least in part on the change in an optical property. Additionally, in some embodiments, aspects of the present disclosure may provide for a method of producing a silicon carbide structure including providing a silicon carbide crystalline material, measuring an optical property along a first axis through the crystalline material, measuring the optical property along a second axis through the crystalline material, and processing the crystalline material based at least in part on the optical property along the first axis and along the second axis. Processing the crystalline material may include various operations, such as modifying, sorting, categorizing, inspecting, and/or evaluating the crystalline material.

In some embodiments, intrinsic point defect engineering may be used to modulate optical properties of a silicon carbide workpiece. For instance, point defect engineering may modify optical properties by increasing, reducing or obtaining a desired, predetermined, or controlled intrinsic point defect concentration (e.g., as opposed to a random intrinsic point defect concentration) to alter the optical properties of the material (e.g., to modify optical properties such as transmission, absorption, reflection, etc., in at least a portion of the visible spectrum). Depending on the embodiment, the point defects can be configured (e.g., through an appropriate local or general thermal, kinetic, and/or chemical process), to compensate for impurities, (e.g., inherent in the crystal growth process or otherwise intentionally incorporated into the material) to alter the optical properties of the material.

More specifically, any defect in a silicon carbide crystal lattice, (e.g., impurities, intrinsic point defects, dislocations, micropipes, stacking faults, etc.) may scatter light or absorb the light. Because it is difficult to make a perfect crystal, it may be desirable to compensate for these defects and make them neutral for the scattering or absorbing of light in a specific region of the wavelength spectrum.

Residual impurities which reduce transparency of silicon carbide crystalline material may include nitrogen and boron and/or other dopants (e.g., vanadium, aluminum, phosphorus, etc.). For very transparent workpieces in the visual spectrum of light, it may be desirable to reduce impurity concentration below the level 1×10¹⁵ cm⁻³. Nitrogen and boron may be incorporated into silicon carbide crystals during the growth from components of a crystal growth system, or by intentional addition. To reduce the effect of these (or other impurities), intrinsic point defects engineering (e.g., vacancies, anti-sites, interstitials, etc.) may be used to compensate residual nitrogen and boron with formation of complexes, (e.g., silicon vacancy-nitrogen) and/or (carbon/silicon vacancy-boron)) which will not scatter or absorb light in the visual spectrum. Other suitable dopants can be used for formation of complexes, such as vanadium, aluminum, phosphorus, or other dopants. At the same time residual intrinsic point defects (after compensation of nitrogen or boron) may be kept at negligible level by, for instance, thermally treating the workpiece at specific temperature and ambient environment.

In some embodiments, aspects of the present disclosure may include modifying portions, (e.g. defined portions) of the silicon carbide crystalline material using local engineering of point defects in the silicon carbide crystalline material. The local engineering of point defects may be implemented using, for instance, a radiation source (e.g., laser) and/or local irradiation of the workpiece with protons, neutrons, etc. In some examples, the local engineering of point defects may be accomplished by emission of a laser below a decomposition threshold of the silicon carbide material.

The local engineering of point defects may modify local optical properties (e.g., transmittance, reflectance, absorption, fluorescence, phosphorescence, luminescence or other optical properties) or other properties (e.g., resistivity, conductivity, thermal conductivity, polytype structure) of the crystalline material. In this way, the silicon carbide material or resulting workpiece can have areas of different optical and/or electrical properties (e.g., resistivity) across the material or resulting workpiece to provide areas on the workpiece providing different optical and/or electrical functions, such as areas of high or low optical transmissivity (e.g., lens portion for human or machine viewing, areas for reflectivity) and/or display, (e.g., display of information regarding the view or otherwise) and/or areas with optically and/or electrically active and/or passive devices (e.g. optically active transistors and/or diodes or other circuitry as part of a smart input/output lensing system for smart or virtual reality glasses).

In some examples, the modification may include increasing or decreasing local point defects in the silicon carbide crystalline material. In some examples, the point defects may introduce impurities or dopants to make certain regions or local areas of the silicon carbide crystalline material more optically transmissive (e.g., transparent) or less optically transmissive (e.g., opaque or absorbing in at least portions of the visible spectrum). In some examples, the local engineering of point defects in the form of silicon and/or carbon vacancies may form complexes with dopants or impurities (e.g., nitrogen, boron, etc.). In some examples, the local engineering of point defects may adjust high absorption characteristics of a portion of the crystalline material in the region of the local point defects from a visual light spectrum to an infrared spectrum, making at least a portion of the crystalline material more transparent to visual light.

In some examples, the local point defect engineering may be operable to create vacancies to accommodate the presence of dopants and/or impurities. For instance, the local engineering of point defects can be implemented in a concentration relative to a concentration of dopants or impurities (e.g., nitrogen and/or impurities) that are present during the crystal growth process. For instance, the local engineering of point defects may be implemented to provide vacancies in the silicon carbide crystalline material at a concentration of about 1×10¹⁵ to about 1×10¹⁸ cm⁻³, such as about 1×10¹⁵ to about 1×10¹⁷ cm⁻³, 1×10¹⁵ to about 1×10¹⁶ cm⁻³. Carbon vacancies may form complexes with nitrogen to provide regions of reduced absorption and increased transparency in the visible light spectrum. Silicon vacancies may form complexes with boron to provide regions of reduced absorption and increased transparency in the visible light spectrum. Aspects of the present disclosure are discussed with reference to point defects that include vacancies for purposes of illustration and discussion. However, other point defects are contemplated by the present disclosure, such as anti-sites, interstitials, or other intrinsic defects or radiation point defects. In some embodiments, the point defects may form complexes with dopants or impurities, for instance to compensate each other, and locally adjust the bandgap of the material (e.g., from deep level to shallow level or vice versa) to increase and/or decrease the resistivity and/or optical transmissivity of the silicon carbide crystalline material.

Aspects of the present disclosure provide a number of technical effects and benefits. Manufacturing crystalline material structures with substantially large thicknesses along a c-axis (or other axis) associated with the structures may provide for the development of custom crystalline material structures and devices not normally feasible with traditional semiconductor manufacturing specifications. Additionally, utilizing the Biederman effect to identify different regions within a crystalline material structure containing various dopant concentrations may provide for isolating specific dopant concentrations and creating unique crystalline material structures with unique properties (e.g., optical properties, electrical properties, etc.). As one example, aspects of the present disclosure are directed to manufacturing crystalline material structures with electrically compensated and substantially clear regions (e.g., or other desired optical properties) across the visible light spectrum, enabling custom manufacturing of optical devices.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “central portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel. “Non-perpendicular” means not perpendicular.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the disclosure are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

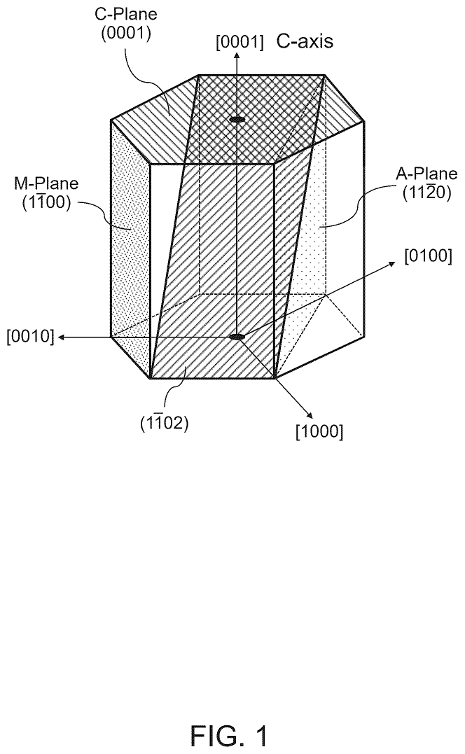

FIG. 1 depicts a first perspective view crystal plane diagram showing the coordinate system for a hexagonal crystal according to example aspects of the present disclosure. FIG. 1 depicts a hexagonal crystal, such as 4H—SiC, in which the C-plane ((0001) plane), corresponding to a [0001] (vertical) crystal direction (e.g., c-axis), is perpendicular to both the M-plane ((11̅00) plane) and the A-plane ((112̅0) plane), and non-perpendicular with the (11̅02) plane). On-axis silicon carbide wafers, or C-face silicon carbide crystalline materials, having small offcut (e.g., less than half a degree from the crystallographic c-plane) are frequently employed as growth substrates for high-quality epitaxial growth of homoepitaxial layers of silicon carbide as well as other materials (e.g., aluminum nitride (AlN) and other Group III nitrides). In addition to C-face silicon carbide crystalline materials, the principles of the present disclosure may also apply to one or more of an A-face, M-face, and {033̅8}-face silicon carbide crystalline materials. In still further embodiments, the principles of the present disclosure may be applicable for embodiments where silicon carbide crystalline materials are formed in various three-dimensional shapes, such as a prism, to leverage birefringence properties of silicon carbide.

As described above, it is also possible to produce vicinal (also known as offcut or off-axis) wafers having end faces that are not parallel to the crystallographic c-plane. Vicinal wafers (e.g., of SiC) having various degrees (e.g., about 0.1°, about 0.25°, about 0.5°, about 0.75°, about 1°, about 2°, about 4°, about 6°, about 8°, or larger) offcut are frequently employed as growth substrates for high-quality epitaxial growth of homoepitaxial layers of silicon carbide as well as other materials (e.g., AlN and other Group III nitrides). Vicinal wafers may be produced either by growing a boule or ingot in a direction away from the c-axis (e.g., growing over a vicinal seed material and sawing the ingot perpendicular to the ingot sidewalls), or by growing an ingot starting with an on-axis seed material and sawing or cutting the ingot at an angle that departs from perpendicular to the ingot sidewalls.

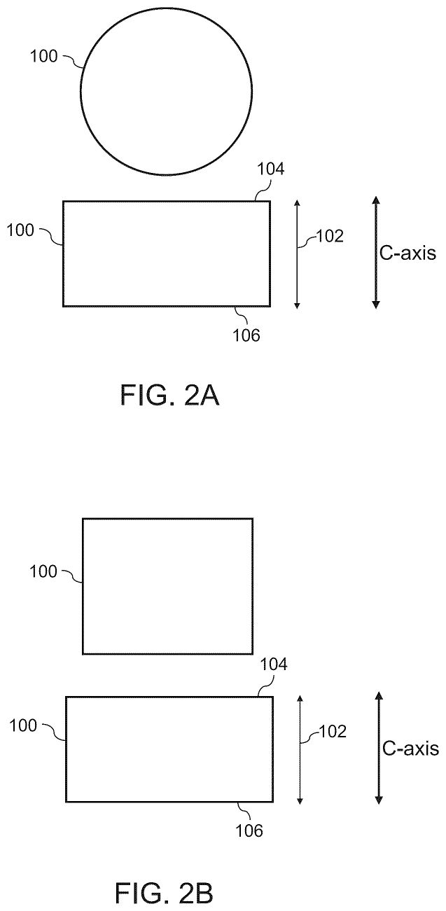

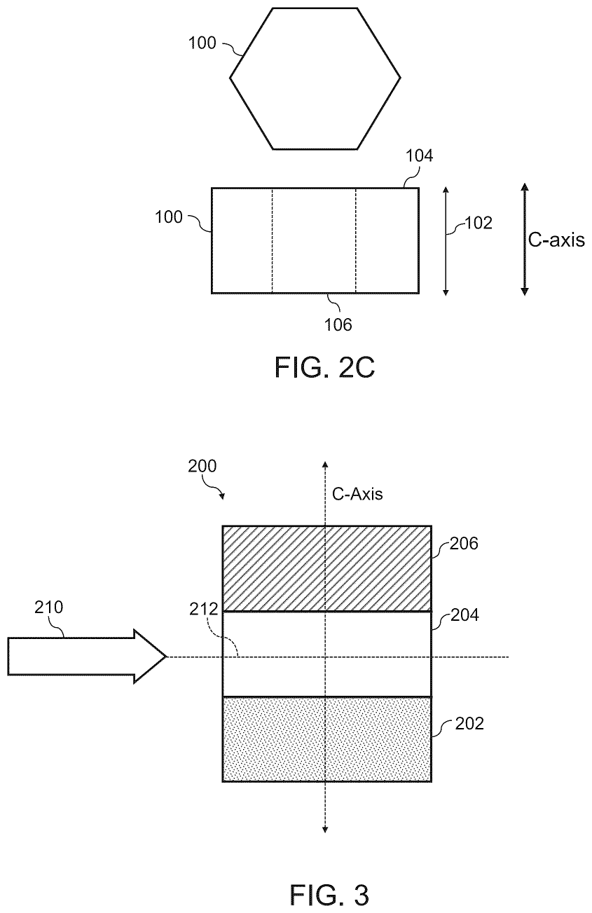

FIG. 2A depicts a top-down view and a side view of an example silicon carbide crystalline material structure 100 according to example aspects of the present disclosure. The structure 100 may be one or more of 4H silicon carbide, 6H silicon carbide, 3C silicon carbide, 15R silicon carbide, semi-insulating silicon carbide, n-type silicon carbide, p-type silicon carbide, or other silicon carbide crystalline material. In some embodiments, the structure 100 may be a preform. The structure 100 may be a cylindrical shape, as depicted, and include a thickness 102 along a c-axis associated with the structure 100. In some embodiments, the structure 100 may have a first surface 104 associated with a c-plane of the crystalline material. The first surface 104 may be associated with a carbon face. The structure may have a second surface 106 opposite the first surface 104 and associated with a c-plane of the crystalline material. The second surface 106 may be associated with a silicon face. However, in some embodiments, the first surface 104 may be associated with a silicon face and the second surface 106 may be a carbon face.

The structure 100 may include an outer diameter between about 100 mm and about 400 mm, such as between about 150 mm to about 300 mm, such as between about 200 mm to about 300 mm. The thickness 102 of the structure 100 may vary, but in some embodiments, the thickness 102 may primarily fall within a higher range for crystalline material structures. For instance, as an example, the thickness 102 of the structure 100 may be between about 10 mm to about 200 mm, such as between about 10 mm to about 75 mm, such as between about 10 mm to about 50 mm. It should be appreciated that the crystalline material structure 100 is depicted for illustrative purposes only and the dimensions within FIG. 2A are not representative of actual dimensions or ratios of dimensions.

Aspects of the present disclosure are discussed with reference to a silicon carbide crystalline material structure having a cylindrical shape for purposes of illustration and discussion. Those of ordinary skill in the art, using the disclosures provided herein, will understand that structures according to examples of the present disclosure may include any suitable shape (e.g., a prism) without deviating from the scope of the present disclosure.

For instance, FIG. 2B depicts a silicon carbide crystalline material structure 100 similar to FIG. 2A, except that the structure 100 of FIG. 2B has a prism shape where a top surface provides a rectangular cross-section. FIG. 2C depicts a silicon carbide crystalline material structure 100 similar to FIG. 2B, except that the structure 100 of FIG. 2C has a prism shape where a top surface provides a rectangular cross-section.

FIGS. 2A-2C depicts structures having a c-plane as a first surface 104 and second surface 106 with a c-axis extending vertically through the structure 100. However, the structures 100 may have other suitable crystal orientations without deviating from the scope of the present disclosure. For instance, the structure may be off-axis or vicinal such that the first surface 104 and second surface 106 is off-axis from the c-plane. The structure 100 may be such that the first surface 104 and the second surface 106 are a different plane, such as an a-plane, m-plane, or between planes.

FIG. 3 depicts a cross-sectional view of a crystalline material structure 200 exhibiting a Biederman effect according to examples of the present disclosure. The structure 200 may be similar to the structure 100 depicted in FIG. 2A. The structure 200 may be a silicon carbide crystalline material. In some embodiments, the crystalline material structure 200 may include a plurality of regions having varying dopant concentrations. Accordingly, these structures may include a dopant distribution across the entire structure with varying levels of dopant concentrations in various regions. For instance, the crystalline material structure 200 may include a first region 202, a second region 204, and a third region 206. The regions may include various dopant concentrations, such as the first region 202 having an increased concentration of nitrogen relative to the second region 204 and the third region 206. The dopants may be intentionally included in the crystalline material structure 200 during crystal growth, or may be the result of impurities included in the crystalline material structure 200 during a crystal growth process (e.g., presence of nitrogen).

In some embodiments, the structure 200 may exhibit a change in an optical property when illuminated with polarized light. For instance, in some embodiments, the structure 200 may have a first absorption coefficient along the c-axis. This may be an integrated absorption coefficient representative of the absorption coefficient along the thickness of the structure 200 in the c-axis direction and may be based on the absorption coefficient of each of the first region 202, second region 204, and third region 206.

In some embodiments, the crystalline material structure 200 comprises an absorption coefficient along a c-axis of the crystalline material that is less than about 0.15 cm⁻¹ over a wavelength range from about 420 nm to about 700 nm. In some embodiments, the crystalline material structure 200 comprises a notch absorption coefficient in a subset of the wavelength range from about 420 nm to about 700 nm.

In some embodiments, the structure 200 may exhibit a uniform optical property along an axis that is different from the c-axis (e.g., generally perpendicular to the c-axis). For instance, when not illuminated with polarized light, the structure 200 may have a second absorption coefficient that is defined by a minimum value and a maximum value that are about 0.15 cm⁻¹ apart over a wavelength range from about 420 nm to about 700 nm along an axis 212 generally perpendicular to the c-axis of the crystalline material (e.g., along the [0010] direction, the [1000] direction, and the [0100] direction).

When illuminated with polarized light 210 along the axis 212 generally perpendicular to a c-axis associated with the structure 200, an optical property (e.g., absorption coefficient) in one or more of the first region 202, second region 204, and/or third region 206 may change due to the Biederman effect. For instance, an absorption coefficient for certain wavelength ranges may increase, causing the first region 202, second region 204, and/or third region 206 crystalline material structure 200 to appear a certain color. In some embodiments, the polarized light 210 may be linearly polarized with a polarization direction that is generally perpendicular or parallel to the c-axis associated with the structure 200.

In some embodiments, each region may exhibit a different change in one or more optical properties when illuminated with polarized light. For instance, the first region 202 may exhibit an increased absorption coefficient for light in a different wavelength range relative to the second region 204 and/or the third region 206. The third region 206 may exhibit an increased absorption coefficient in a different wavelength range relative to the first region 202 and/or the second region 204. In some embodiments, a region, such as the second region 204, may not exhibit a change in optical property.

More particularly, in some embodiments, the first region 202 may exhibit an increase in the absorption coefficient between wavelengths of about 450 nm to about 495 nm when the structure 200 is illuminated with polarized light 210 along an axis 212 that is generally perpendicular to the c-axis (e.g., along the [0010] direction, the [1000] direction, the [0100] direction). This may cause the first region 202 to appear blue when viewed along the axis 212. This may be due to the presence of increased nitrogen dopant or other dopants (e.g., n-type dopants) in the first region 202 relative to the other regions.

The third region 206 may exhibit an increase in the light absorption coefficient between wavelengths of about 570 nm to about 590 nm when a structure is illuminated with polarized light 210 along an axis 212 that is generally perpendicular to the c-axis (e.g., along the [0010] direction, the [1000] direction, the [0100] direction). This may cause the third region 206 to appear yellow when viewed along the axis 212. This may be due to a lack of nitrogen dopants and/or the presence of increased p-type dopants (e.g., boron) in the third region 206 relative to the other regions.

The second region 204 may not exhibit an increase absorption coefficient when illuminated with polarized light 210 along the axis 212. The second region 204 may be an electrically compensated region (e.g., dopants are balanced such that the second region is not n-type or p-type). In embodiments where the structure 200 has an absorption coefficient along the c-axis that is less than about 0.15 cm⁻¹ over a wavelength range from about 420 nm to about 700 nm, the second region 204 may appear clear when viewed along the axis 212.

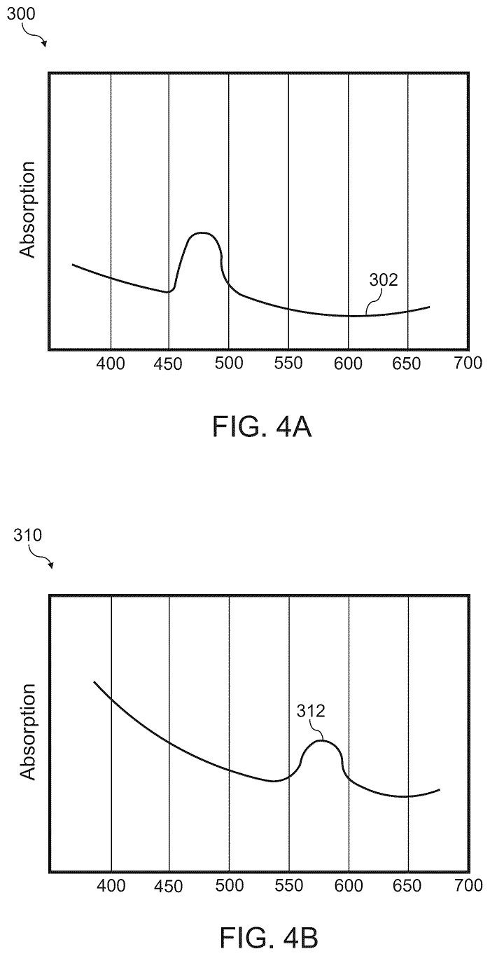

FIGS. 4A-B depict light absorption graphs associated with crystalline material structures according to example aspects of the present disclosure. FIG. 4A depicts a first light absorption graph 300 with a first trend line 302 associated with the first region 202. The first trend line 302 indicates an increase in the absorption coefficient between wavelengths of about 450 nm to about 495 nm when a structure is illuminated with polarized light along an axis that is generally perpendicular to the c-axis (e.g., along the [0010] direction, the [1000] direction, the [0100] direction). An increase in this range may be indicative of the color blue and may be associated with a primarily nitrogen dopant concentration in a region of a crystalline material structure.

FIG. 4B depicts a second light absorption graph 310 with a second trend line 312 associated with the third region 206. The second trend line 312 indicates an increase in the light absorption coefficient between wavelengths of about 570 nm to about 590 nm when a structure is illuminated with polarized light along an axis that is generally perpendicular to the c-axis (e.g., along the [0010] direction, the [1000] direction, the [0100] direction). An increase in this range may be indicative of the color yellow and may be associated with a primarily p-type dopant concentration in a region of a crystalline material structure.

FIG. 3 depicts one example silicon carbide crystalline material structure 200 for purposes of illustration and discussion. The silicon carbide crystalline material structure may include a different number or type of regions or distributions of dopants without deviating from the scope of the present disclosure. The size and/or thickness of the regions may vary.

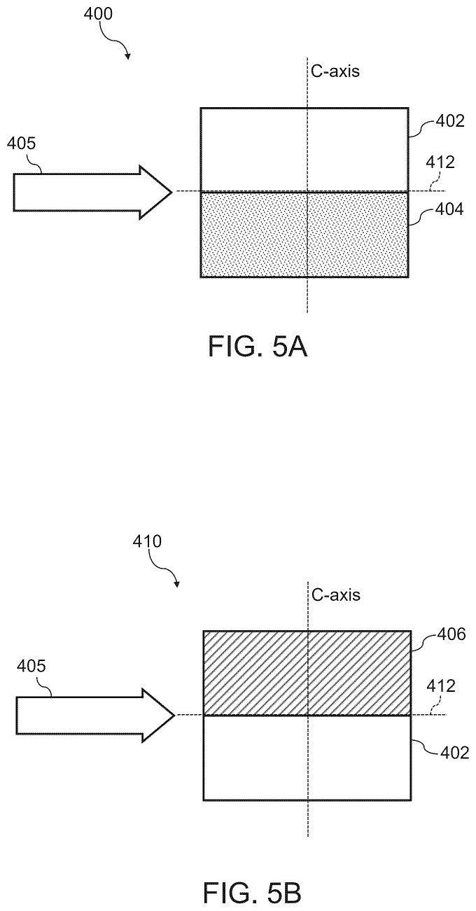

For instance, FIG. 5A depicts a silicon carbide crystalline material structure 400 having a first region 402 and a second region 404. The structure 400 may be exposed to polarized light 405 along an axis 412 perpendicular or substantially perpendicular to a c-axis of the structure 400. The two regions (e.g., the first region 402 and/or the second region 404) may be characterized by their respective changes in optical properties when exposed to the polarized light 405. For instance, as an example, the first region 402 of the structure 400 may exhibit no change in optical property and may be an electrically compensated region. The second region 404 may exhibit an increased absorption coefficient associated with the wavelength range of about 450 nm to about 495 nm (e.g., blue light) and may include an increased nitrogen dopant concentration relative to the first region 402.

FIG. 5B depicts another example silicon carbide crystalline material structure 410 having a first region 402 and a second region 406. The structure 400 may be exposed to polarized light 405 along an axis 412 perpendicular or substantially perpendicular to a c-axis of the structure 400. The two regions (e.g., the first region 402 and/or the second region 406) may be characterized by their respective changes in optical properties when exposed to the polarized light 405. For instance, as an example, the first region 402 of the structure 400 may exhibit no change in optical property and may be an electrically compensated region. The second region 406 may exhibit an increased absorption coefficient within the wavelength range of about 570 nm to about 590 nm (e.g., yellow light) and may include a lack of nitrogen dopants relative to the first region 404 and/or an increased p-type dopant concentration relative to the first region 402.

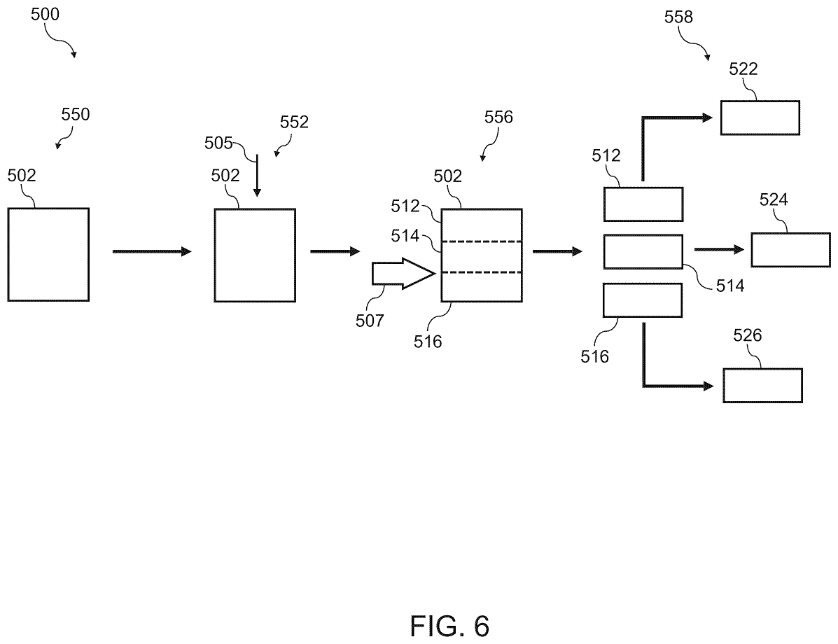

FIG. 6 depicts a crystalline material structure processing method 500 according to example aspects of the present disclosure. The method 500 includes operations performed in a particular order for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 550, the method 500 can include providing a silicon carbide crystalline material structure 502. The structure 502 may be similar to any of the silicon carbide crystalline material structures 502 provided herein, such as the structure 100 of FIG. 2 or the structure 200 of FIG. 3. In some embodiments, the structure 502 may be a workpiece, wafer, ingot, boule, or preform. The structure 502 may be or may include one or more of 4H silicon carbide, 6H silicon carbide, semi-insulating silicon carbide, n-type silicon carbide, or p-type silicon carbide. In some embodiments, the thickness of the structure 502 may be between about 10 mm to about 200 mm, such as between about 10 mm to about 75 mm, such as between about 10 mm to about 50 mm.

In some embodiments, the structure 502 may be grown through a crystal growth process, such as a physical vapor transport (PVT) process. In some embodiments, the crystal growth process may be any of the crystal growth processes described in U.S. Pat. No. 12,024,794, titled “Reduced optical absorption for silicon carbide crystalline materials” filed on Jun. 17, 2021, which is incorporated herein by reference for all purposes.

At 552, the structure 502 may undergo certain processing to modify optical properties of the structure 502. For instance, the structure 502 may undergo a thermal conditioning process 505 or other process to provide a desired optical property at 552. In some embodiments, the thermal conditioning process 505 provides a structure 502 with an absorption coefficient is less than about 0.15 cm⁻¹ over a wavelength range from about 420 nm to about 700 nm along a c-axis of the crystalline material.

In some embodiments, the thermal conditioning process 505 comprises annealing the structure 502 at a temperature in a range from about 1300° C. to about 2600° C., such as in a range from about 2000° C. to about 2600° C. In certain embodiments, the thermal conditioning process 505 comprises cooling the structure 502 down from the temperature at a rate in a range from about 0.5° C. to about 5° C. per minute. In certain embodiments, the temperature is in a range from about 1300° C. to about 2000° C. In certain embodiments, the thermal conditioning process 505 comprises cooling the crystalline material structure 502 down from the temperature at a rate in a range from above about 5° C. to about 100° C. per minute.

In some embodiments, the thermal conditioning process 505 comprises providing one or more laser emissions to the crystalline material structure 502. The one or more laser emissions may be configured to modify an optical property of the crystalline material structure 502. The one or more laser emissions may be configured to modify the absorption coefficient of the silicon carbide crystalline material structure 502. Any suitable process may be used to modify one or more optical properties (e.g., absorption coefficient) of the crystalline material without deviating from the scope of the present disclosure. In some example embodiments, optical properties of the structure 502 may be measured prior to laser processing. For instance, optical properties (e.g., LIDT properties) throughout the structure 502 may be used to determine laser parameters for modifying different portions of the structure 502.

In some embodiments, the thermal conditioning process 505 comprises one or more of the processes described in U.S. Pat. No. 12,024,794, titled “Reduced optical absorption for silicon carbide crystalline materials” filed on Jun. 17, 2021, which is incorporated herein by reference for all purposes.

At 556, the method may include illuminating the structure 502 with polarized light 507 along an axis that is generally perpendicular to the c-axis of the structure 502 (e.g., along the [0010] direction, the [1000] direction, the [0100] direction). The polarized light 507 may be linearly polarized with a polarization direction that is generally perpendicular or generally parallel to the c-axis of the structure 502. As described above, the structure 502 may exhibit a change in one or more optical properties when illuminated with the polarized light.

More particularly, as illustrated at 556 in FIG. 6, the structure 502 may include a first region 512, a second region 514, and a third region 516 that exhibit different changes in one or more optical properties (e.g., different change in absorption coefficient) when illuminated with the polarized light 507. For instance, for example purposes only, the first region 512 may exhibit an increase in absorption coefficient in a wavelength range of about 570 nm to about 590 nm (e.g., yellow light). The second region 514 may exhibit no change in optical property (e.g., no change in absorption coefficient). The third region 516 may exhibit an increase in absorption coefficient in a wavelength range of about 450 nm to about 495 nm (e.g., blue light).

The example regions and change in optical property of regions 512, 514, and 516 are provided for purposes of illustration and discussion. The structure 502 may include any distribution of regions exhibiting different changes in optical properties when illuminated with polarized light 507 without deviating from the scope of the present disclosure.

At 558, the method may include processing the structure 502 based on the change in optical property at 556. Processing the structure 502 may include any action based on the change in optical property. Processing the structure may include a variety of operations and/or steps.

For instance, processing the crystalline material structure 502 may include modifying, sorting, inspecting, and/or evaluating the crystalline material based on the change in an optical property. As an example, one or more physical properties of the crystalline material structure 502 may be modified based on the change in optical property. Physical properties may include shape, thickness, diameter, edge count, or surface count. Physical properties may be modified by cutting (e.g., with a laser, wire saw, grinding apparatus), removing material (e.g., grinding, polishing, lapping), and/or adding material to the crystalline material structure 502.

Additionally, as an example, the crystalline material may be sorted into a group of crystalline workpieces based on the optical property associated with each group. For instance, sections or regions of the crystalline material structure may be categorized and/or sorted into different bins or categories before or after physical modification of the crystalline material structure 502. Additionally, in some embodiments, the crystalline material structure 502 may be inspected for one or more defects. In some embodiments, the crystalline material structure 502 may be evaluated, inspected, and/or analyzed for polytype inclusions and/or polytype transitions. In some embodiments, the crystalline material structure 502 may be evaluated, inspected, and/or analyzed for foreign material inclusions and/or voids. In some embodiments, a dopant concentration of at least a portion of the crystalline material may be evaluated based on the change in the optical property. Other suitable operations may be performed on the crystalline material structure as part of processing the crystalline material structure based at least in part on its optical property or properties (e.g., change in optical property(s)) without deviating from the scope of the present disclosure.

In some examples, processing the structure 502 may include modifying the structure (e.g., cutting or removing portions of the structure), evaluating the structure 502 (e.g., assessing quality, identifying defects, etc.), sorting/classifying the structure 502 (e.g., sorting the structure 502 or regions of the structure 502 into different categories or bins based on the different optical property(s)), subjecting the structure 502 to further processing (e.g., further thermal conditioning, surface processing operations, etc.), or other operations or simply to bin the optical material into different groups with certain optical properties for sale or for further processing for use in appropriate applications.

In the example depicted in FIG. 6, the method 500 includes modifying the structure 502 to separate the different regions 512, 514, and 516. For instance, the region 512 exhibiting a first optical property (e.g., increased optical absorption coefficient in the yellow wavelength range) may be separated from the remainder of the structure 502. The region 514 exhibiting a different optical property (e.g., no change in optical absorption coefficient or reduced optical absorption coefficient across the visual spectrum) can be separated from the remainder of the structure 502. The region 516 exhibiting a different optical property (e.g., increase in absorption coefficient in the blue wavelength range) may be separated from the remainder of the structure 502. Any suitable technique may be used for separation, such as laser-based cutting, implant-based cutting/separation, wire saw based cutting, grinding, or other suitable technique. In some embodiments, the regions 516 are categorized into different categories or bins based on the change in optical property before or after separation of the remainder of the structure 502.

In some embodiments, the structure 502 may be processed using one or more lasers. In these example embodiments, optical properties of the structure 502 may be measured prior to laser processing. For instance, optical properties (e.g., LIDT properties) throughout the structure 502 may be used to determine laser parameters for cutting and/or modifying different portions of the structure 502

The respective regions 512, 514, and 516 may then be used for different purposes or to form different types of downstream devices, such as different optical devices or optical devices with different performance. For instance, the region 512 may be used to form an optical device 522 (e.g., a filter) exhibiting a desired response (e.g., increased absorption coefficient in the yellow wavelength range) to polarized light. The region 514 may be used to form an optical device 524 (e.g., a lens) exhibiting a desired response to polarized light (e.g., no change in absorption coefficient). The region 516 may be used to form an optical device 526 (e.g., a filter) exhibiting a desired response to polarized light (e.g., increased absorption coefficient in the blue wavelength range).

In some embodiments, one or more of the optical devices 522, 524, and/or 526, and/or the structure 502 may be subjected to further processing after separation or removal of the optical devices 522, 524, and/or 526. For instance, one or more of the optical devices 522, 524, 526 and/or the structure 502 may be subjected to the thermal process 505 to enhance optical characteristics. One or more of the optical devices 522, 524, 526 and/or the structure 502 may be subjected to laser processing and/or surface processing (e.g., grinding, lapping, polishing, chemical-mechanical polishing, etc.). One or more of the optical devices 522, 524, 526 and/or the structure 502 may be processed to include a coating (e.g., a reflective coating, anti-reflective coating, diffusive coating, filter coating, etc.). One or more of the optical devices 522, 524, 526 and/or the structure 502 may be processed to have a textured surface or other surface to provide a desired optical effect (e.g., diffusion, scattering, transmission, etc.).

In some embodiments, to facilitate measuring changes in optical properties or otherwise to detect internal properties of a silicon carbide crystalline material structure, such as any of the structures provided herein, one or more surfaces of the silicon carbide crystalline material structure 502 may include a window (e.g., a polished window). The window may have a surface roughness in a range of about 0.5 nm to about 100 nm, such as in a range of about 0.5 nm to about 60 nm, such as in a range of about 0.5 nm to about 25 nm. In some embodiments, a silicon carbide crystalline material structure 502 may include one or more windows to allow for measurement of optical properties (e.g., using a spectrophotometer) or other properties along multiple different axes of the structure 502.

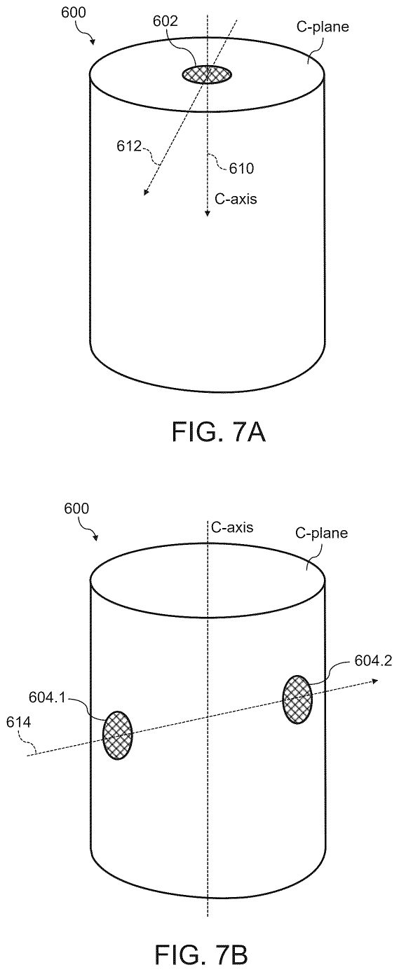

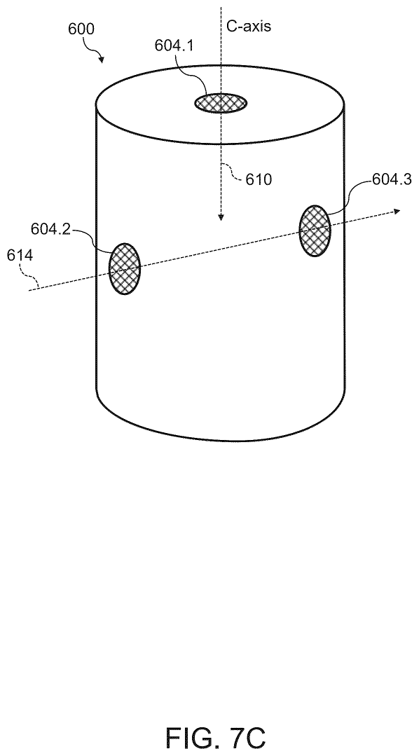

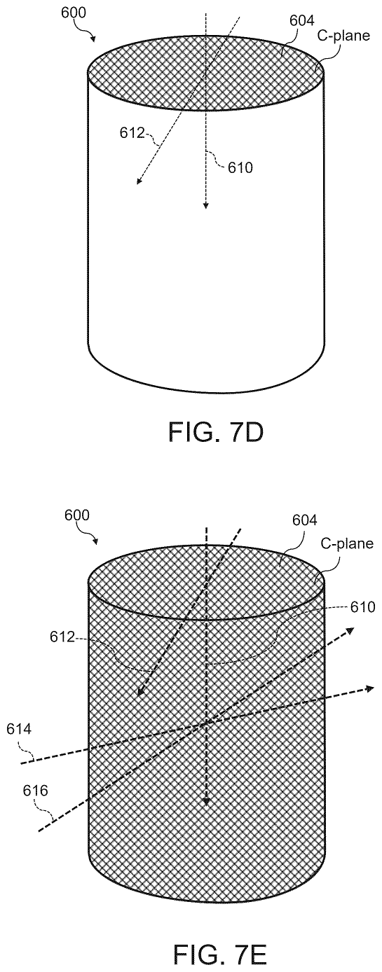

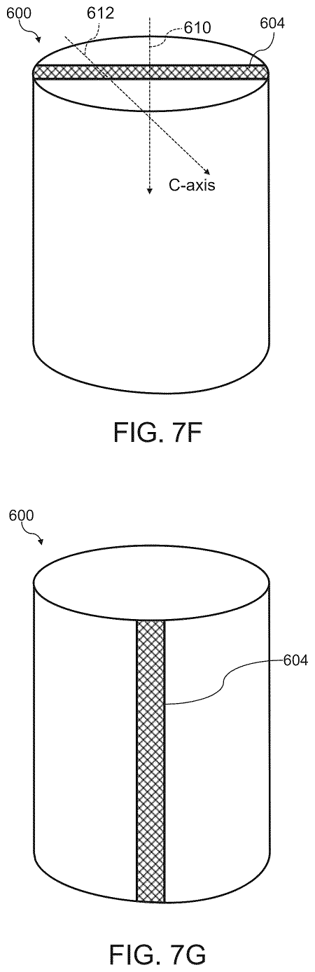

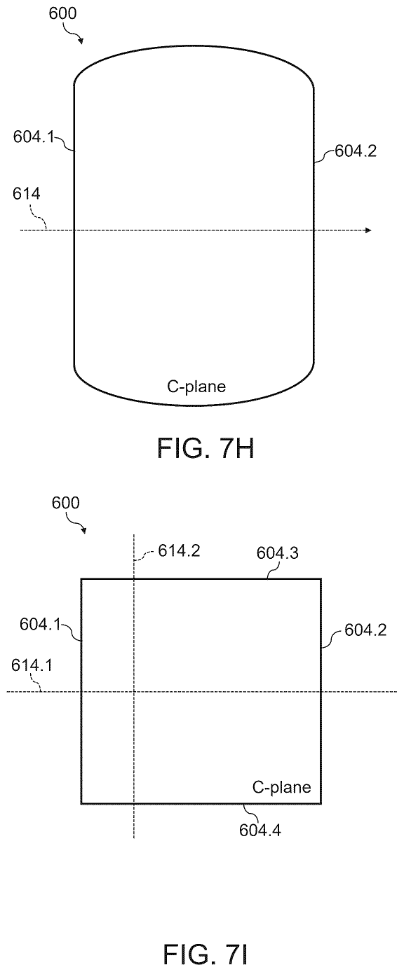

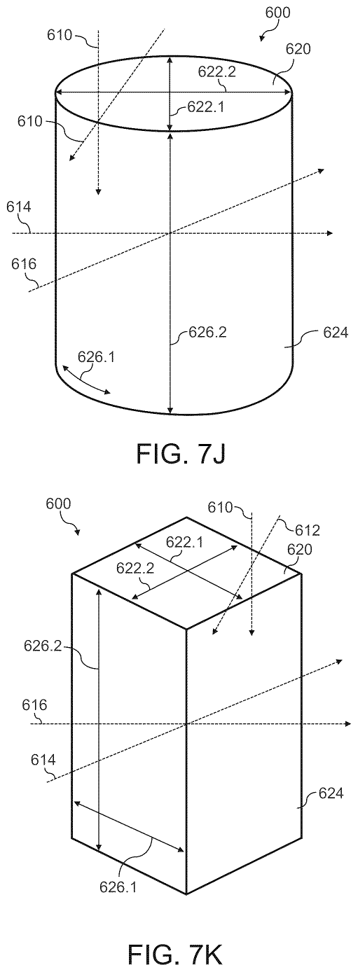

FIGS. 7A-7K depict crystalline material structures 600 having at least one window 604 on a surface of the structure 600 according to example embodiments of the present disclosure. The window 602 may have a surface roughness in a range of about 0.5 nm to about 100 nm, such as in a range of about 0.5 nm to about 60 nm, such as in a range of about 0.5 nm to about 25 nm.

For instance, FIG. 7A depicts a silicon carbide crystalline material structure 600 including a window 602 on a portion of a surface corresponding to a c-plane of the structure 600. The window 602 may permit measurement of an optical property along an axis 610 corresponding to a c-axis of the structure 600. In addition, the window 602 may permit measurement of an optical property along an axis 612 that is non-perpendicular to the axis 610 corresponding to the c-axis of the structure 600.

FIG. 7B depicts a silicon carbide crystalline material structure 600 having windows 604.1, 604.2 on portions of opposing surfaces of the structure 600. The windows 604.1, 604.2 may allow for measurement of an optical property along an axis 614 generally perpendicular to the c-axis of the structure 600. The windows 604.1, 604.2 may be arranged to allow radiation associated with a measurement to pass through the entire structure 600 from a location outside window 604.1 to a detector outside window 604.2.

FIG. 7C depicts a silicon carbide crystalline material structure 600 having a first window 604.1 on a portion of a surface corresponding to a c-plane of the structure 600. The structure 600 includes second windows 604.2, 604.3 on portions of opposing surfaces of the structure 600. The window 604.1 may allow measurement of an optical property along an axis 610 corresponding to a c-axis of the structure 600. The windows 604.2, 604.3 may allow for measurement of an optical property along an axis 614 generally perpendicular to the c-axis of the structure 600 and other axes extending from an angle corresponding to the c-plane.

FIG. 7D depicts a silicon carbide crystalline material structure 600 similar to that of FIG. 7A. However, in FIG. 7D, the window 604 on the surface corresponding to the c-plane is on substantially the entire surface. The window 604 may permit measurement of an optical property along an axis 610 corresponding to a c-axis of the structure 600. In addition, the window 604 may permit measurement of an optical property along an axis 612 that is non-perpendicular to the axis 610 corresponding to the c-axis of the structure 600.

FIG. 7E depicts a silicon carbide crystalline material structure 600 similar to that of FIG. 7A. However, in FIG. 7E, surfaces of the structure 600 may be configured to provide a window 604. For instance, surfaces of the structure 600 may have a surface roughness in a range of about 0.5 nm to about 100 nm, such as in a range of about 0.5 nm to about 60 nm, such as in a range of about 0.5 nm to about 25 nm. This may allow for measurement of optical properties along many different axes through the structure 600. For instance, the window 604 may allow for measurement of an optical property along an axis 610 corresponding to a c-axis of the structure 600. The window 604 may permit measurement of an optical property along an axis 612 that is non-perpendicular to the axis 610. The window 604 may permit measurement of an optical property along an axis 614 that is generally perpendicular to the axis 610 corresponding to the c-axis. The window 604 may permit measurement of an optical property along an axis 616 that is non-perpendicular to the axis 614.

Any of the windows 604 may have any suitable shape without deviating from the scope of the present disclosure. For instance, FIG. 7F depicts a linear shaped polished window 604 extending across a surface of the structure 600 corresponding to a c-plane of the structure. The linear shaped window 604 may facilitate measurement of optical properties along many different axes through the structure 600. The window 604 may permit measurement of an optical property along an axis 610 corresponding to a c-axis of the structure 600. In addition, the window 604 may permit measurement of an optical property along an axis 612 that is non-perpendicular to the axis 610 corresponding to the c-axis of the structure 600.

FIG. 7G depicts a linear shaped polished window 604 extending across a surface of the structure 600 corresponding to plane that is generally perpendicular to a c-plane of the structure. The linear shaped window 604 may facilitate measurement of optical properties along many different axes through the structure 502, such as an axis generally perpendicular to the c-axis and at least one axis that is different from the axis generally perpendicular to the c-axis.

FIG. 7H depicts a top-down view of an example silicon carbide crystalline material structure 600 according to examples of the present disclosure viewing a surface corresponding to the c-plane. In FIG. 7H, windows 604.1 and 604.2 provide flat surfaces for the structure 600 along a plane generally perpendicular to the c-plane. The windows 604.1 and 604.2 may be provided by grinding and/or polishing at least a portion of the cylindrical surface of the structure 600 to provide the flat surfaces. The windows 604.1 and 604.2 may facilitate measurement of optical properties along many different axes through the structure 600, such as an axis 614 generally perpendicular to the c-axis.

FIG. 7I depicts a top-down view of an example silicon carbide crystalline material structure 600 according to examples of the present disclosure. In FIG. 7I, windows 604.1, 604.2, 604.3, and 604.4 provide flat surfaces for the structure 600 along a plane generally perpendicular to the c-plane. The windows 604.1, 604.2, 604.3, and 604.4 may be provided by grinding and/or polishing a cylindrical surface of the structure 600 to provide the flat surfaces. The windows 604.1, 604.2, 604.3, and 604.4 may facilitate measurement of optical properties along many different axes through the structure 600, such as along different axes 614.1, 614.2 that are generally perpendicular to the c-axis.

Aspects of the present disclosure are discussed with measuring properties of a crystalline material structure along different axes, planes, surfaces, or directions for purposes of illustration and discussion. Those of ordinary skill in the art will understand that properties of the crystalline material structure may be measured along multiple different axes, surfaces, and/or crystal planes, off-axis planes, and/or between crystal planes without deviating from the scope of the present disclosure.

For instance, FIG. 7J depicts a silicon carbide crystalline material structure 600. One or more surfaces of the structure 600 may include or may be polished windows as described above. As illustrated, optical properties may be measured along any of various surfaces, dimensions, axes, directions, through the crystalline material of the structure 600.

More particularly, the crystalline material structure 600 may include a surface 620 (e.g., corresponding to a c-plane or other plane) and a rounded sidewall surface 624. Measurements of optical properties or other properties may occur along the surface 620 and/or along the rounded sidewall surface 624. For instance, measurements may be made along at least two dimensions or directions along the surface 620 and/or the rounded sidewall surface 624. For instance, measurements may be made along a first dimension 622.1 and a second dimension 622.2 of the surface 620. Measurements may be made along a first dimension 626.1 and a second dimension 626.2 of the rounded sidewall surface 624.

Measurement may be used to determine optical properties associated with an area (e.g., surface area) of at least a portion of one or more surfaces of the crystalline material structure 600 (e.g., surface 620 and/or surface 624). In addition and/or in the alternative, measurements may be made along two or more directions of different planes on a surface or in the interior of the crystalline material structure 600, such as along a c-plane, m-plane, a-plane or other plane.

Measurements may be used to determine optical properties along many different axes through the structure 600. For instance, measurements may be used to determine an optical property along an axis 610 corresponding to a c-axis of the structure 600 and an optical property along an axis 612 that is non-perpendicular to the axis 610. Measurements may be used to determine an optical property along an axis 614 that is generally perpendicular to the axis 610 corresponding to the c-axis and an optical property along an axis 616 that is non-perpendicular to the axis 614. Measurements may be made along any axis or direction through the structure 600, along one or more dimensions of any surface of the structure 600, and/or along one or more crystal planes on a surface and/or in an interior of the structure 600 without deviating from the scope of the present disclosure. Accordingly, the optical properties of the structure 600 can be mapped for different regions or planes over different areas or volumes of the structure 600. Such information can be used to form various optical workpieces from the structure 600 with the same or different optical properties.

In some examples, measuring optical properties may allow for characterization of defects and their effects on optical properties from different directions. Defects associated with dislocations (e.g., threading edge dislocations, screw dislocations, micropipes, basal plane dislocations, etc.) may scatter or absorb light transmitting through the crystalline material. Defects have been detected, such as dislocation defects have been detected using, for instance, x-ray topography, etching techniques and other imaging techniques. However, according to aspects of the present disclosure, defects can be detected or analyzing by looking at different optical response to light transmitted through the defect, such as different absorption and/or scattering.

Measuring along multiple axes or directions may allow for characterization of the defects. For instance, depending on the size of the defect (e.g., dislocation defect), the defect may be too small to be an optical scatterer, but may still cause absorption due to the electrical nature of the defect. In addition, depending on the direction of light through the defect, the defect may or may not scatter light. In this regard, measuring optical properties along multiple axes or directions may allow for characterization of the defects.

In some embodiments, a crystalline material structure according to examples of the present disclosure may have defect density in the following ranges:
Threading edge dislocation: about 500 to about 10,000 cm⁻²
Screw dislocations: about 50 to about 2000 cm⁻², such as about 50 to about 1000 cm⁻²
Basal plane dislocations: 0 to about 2500 cm⁻², such as about 50 to about 1000 cm⁻²
Micropipe: 0 to about 1 cm⁻², such as 0 to about 0.5 cm⁻² such as about 0.05 to about 1 cm⁻², such as 0 to about 0.05 cm⁻².

Aspects of the present disclosure are discussed with reference to a cylindrical shaped structure 600 for purposes of illustration and discussion. However, any of the structures provided herein may have any suitable shape or cross-sections, such as a polygonal cross-section. For instance, FIG. 7K measurement of optical properties along multiple surfaces, dimensions, axes, and planes of a structure 600 similar to that shown in FIG. 7J. However, the structure 600 has a polygonal cross-section (rectangular, hexagonal cross-section).

The examples of FIGS. 7A-7K and in other figures of the present disclosure provide a crystalline material structure with a top surface corresponding to a c-plane of the crystalline material for purposes of illustration and discussion. However, the top surface of the structure may correspond to any plane or may be off-axis with respect to any plane of the crystalline material without deviating from the scope of the present disclosure. For instance, the top surface may correspond to an m-plane, a-plane, or other plane such as a {333̅8} plane of the crystalline material structure. In some embodiments, the top surface may be off-axis with respect to the c-plane or other plane, such as about 0.1°, about 0.25°, about 0.5°, about 0.75°, about 1°, about 2°, about 4°, about 6°, about 8°, or larger relative to the c-plane.

In some examples, measurements of optical properties along multiple different axes, directions, surfaces, planes, etc. may be used to assess defects and their effects on optical properties when measured from different directions along multiple different axes, directions, surfaces, planes, etc. As one example, dislocations with respect to crystallographic orientation may be assessed as defects along with their potential impact on absorption characteristics when measured from different directions.

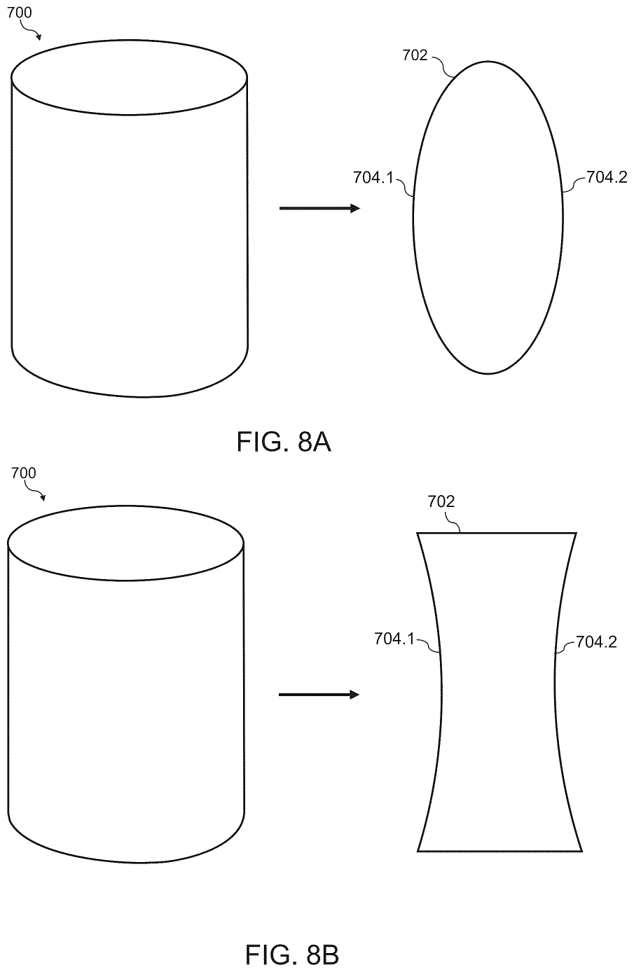

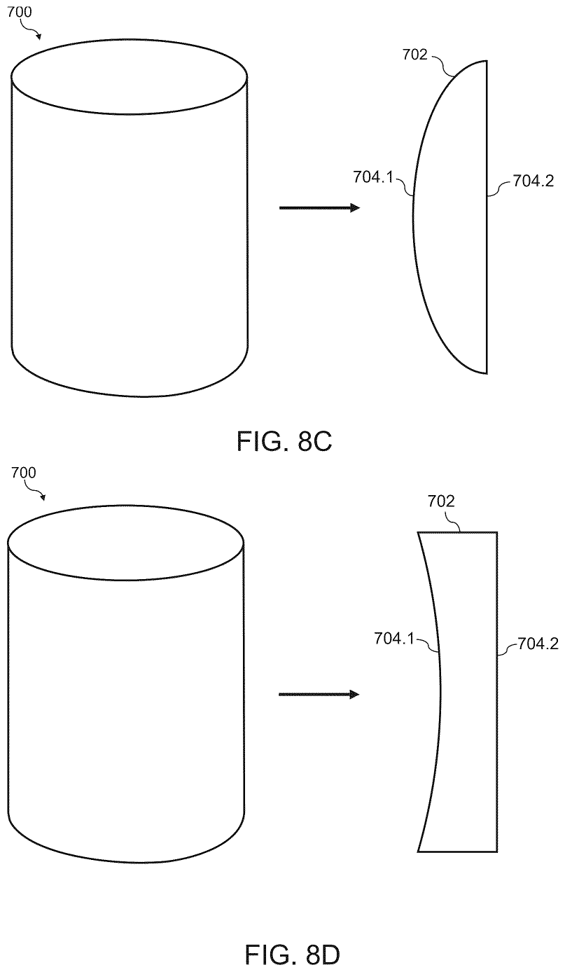

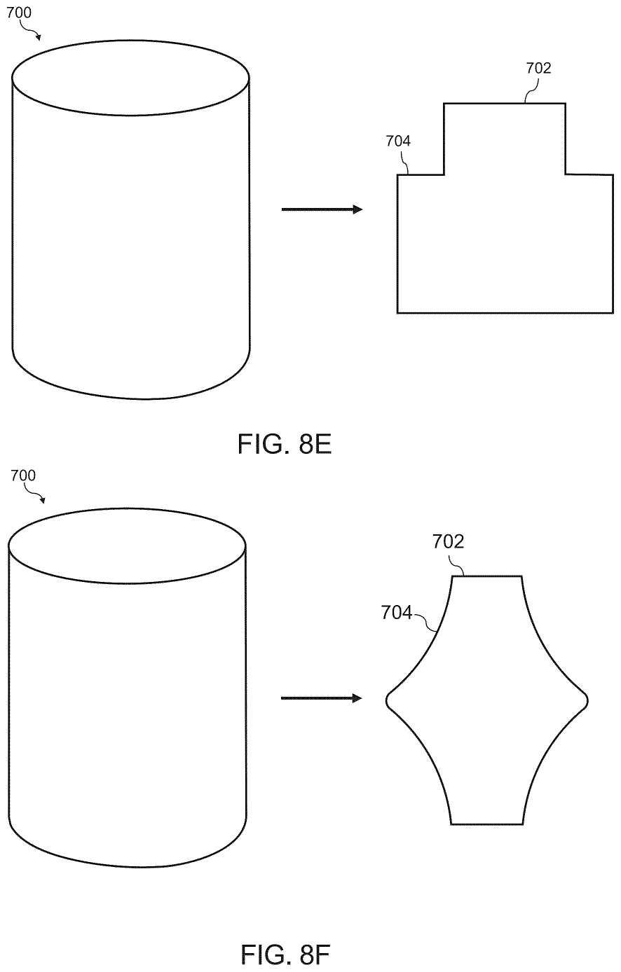

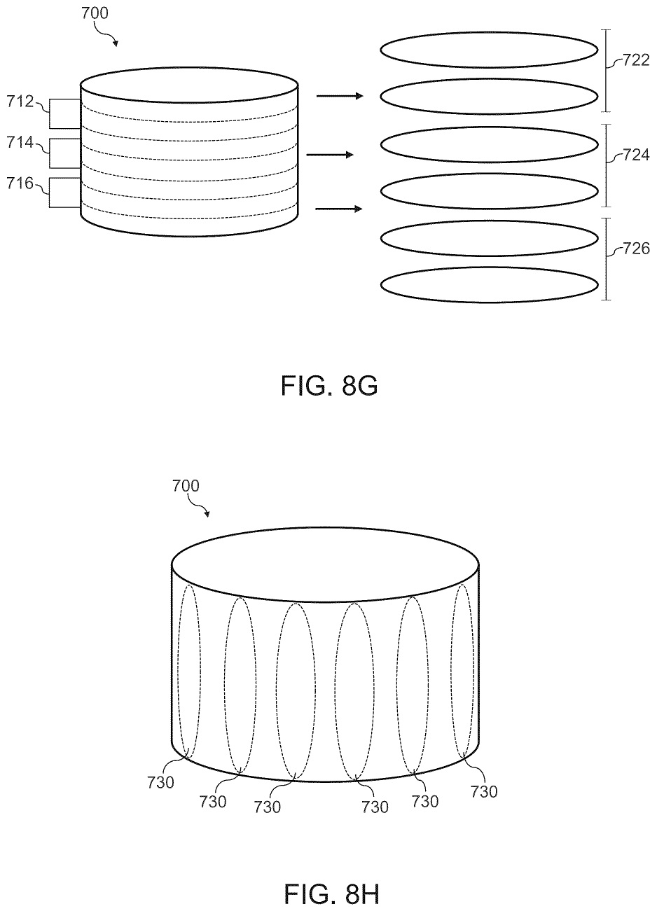

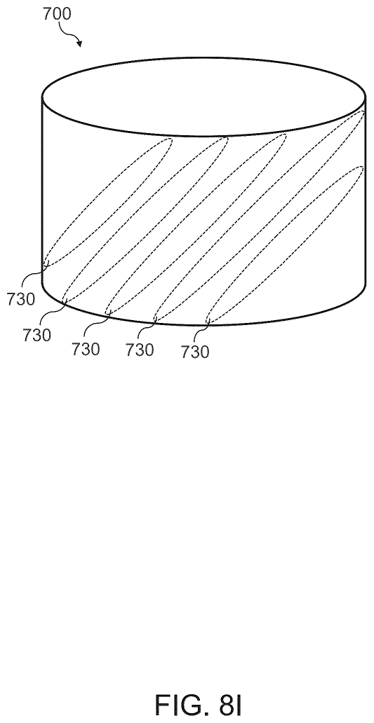

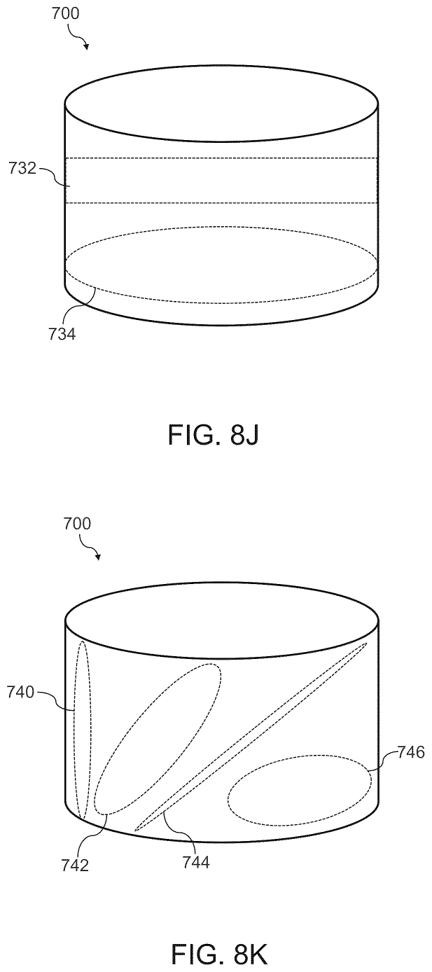

As discussed above, examples of the present disclosure may provide a structure (e.g., a preform) which may be processed (e.g., modified by cutting or removing portions of the structure) to provide a downstream device, such as an optical device, optoelectrical device, electrical device, etc. FIGS. 8A-8K depict example modifications of a structure 700 (e.g., a preform) to form various optical devices. The structure 700 may be any of the silicon carbide crystalline material structures provided herein.

In some embodiments, each of the structures 700 may have a first absorption coefficient that is less than about 0.15 cm⁻¹ over a wavelength range from about 420 nm to about 700 nm along a c-axis of the crystalline material structure 700. In some embodiments, the structures 700 may exhibit a change in a second absorption coefficient along an axis generally perpendicular to the c-axis when illuminated with polarized light along the axis generally perpendicular to the c-axis. In some embodiments, the structures 700 may have a second absorption coefficient that is defined by a minimum value and a maximum value that are about 0.15 cm⁻¹ apart over a wavelength range from about 420 nm to about 700 nm along a second axis generally perpendicular to the c-axis of the crystalline material structure 700.

In some embodiments, the structure 700 may be modified by cutting (e.g., by laser, wire saw, etc.) or otherwise removing portions of the structure 700 to form a downstream device. In some embodiments, the structure 700 is modified based at least in part on a change in optical property when illuminated with polarized light of one or more portions or regions of the structure 700. In some embodiments, the structure 700 is modified based at least in part on optical properties measured across a plurality of different axes (e.g., a first axis and a second axis) of the structure 700.

As one example, FIG. 8A depicts example modification of an example preform structure 700 to yield an optical device 702. The optical device 702 may have one or more curved surfaces. For instance, the optical device 702 may have a first convex surface 704.1 and a second convex surface 704.2 that is opposite the first surface 704.1. In some examples, the optical device 702 may comprise or be a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device.

FIG. 8B depicts modification of an example preform structure 700 to yield an optical device 702. The optical device 702 may have one or more curved surfaces. For instance, the optical device 702 may have a first concave surface 704.1 and a second concave surface 704.2 that is opposite the first concave surface 704.2. In some examples, the optical device 702 may comprise or may be a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device.

FIG. 8C depicts modification of an example preform structure 700 to yield an optical device 702. The optical device 702 may have one curved convex surface 704.1 and one flat surface 704.2. In some examples, the optical device 702 may comprise or be a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device.

FIG. 8D depicts modification of an example preform structure 700 to yield an optical device 702. The optical device 702 may have one curved concave surface 704.1 and one flat surface 704.2. In some examples, the optical device 702 may comprise or be a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device.

FIG. 8E depicts modification of an example preform structure 700 to yield an optical device 702. The optical device 702 may have a non-linear surface 704 (e.g., stepped surface). In some examples, the optical device 702 may comprise or may be a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device.

FIG. 8F depicts modification of an example preform structure 700 to yield an optical device 702. The optical device 702 may have a non-linear surface 704 (e.g., a curved surface). In some examples, the optical device 702 may be a lens, prism, collimator, beam splitter, grating, polarizer, filter (e.g., high pass filter, low pass filter, notch filter, bandpass filter, etc.), Fresnel lens, optical waveguide and/or a refractor structure.

FIGS. 8A-8F depict example optical devices that may be formed from a structure for purposes of illustration and discussion. Those of ordinary skill in the art, using the disclosures provided herein, will understand that many different shapes, sizes, surfaces, facets, etc. may be formed from a structure, such as preform structure 700, without deviating from the scope of the present disclosure. In addition, FIGS. 8A-8F depict only a single optical device that may be formed from a structure 700 for purposes of illustration and discussion. Those of ordinary skill in the art, using the disclosures provided herein, will understand that multiple optical devices may be formed from a structure 700 without deviating from the scope of the present disclosure.

For instance, FIG. 8G depicts a structure 700. The structure 700 may be analyzed using one or more of the techniques provided herein (e.g., using polarized light at a direction that is generally perpendicular to the c-axis) to identify different regions 712, 714, and 716 of the structure 700. The different regions may exhibit different changes in an optical property when illuminated with polarized light. For instance, region 712 may exhibit an increase in absorption coefficient in a wavelength range between about 450 nm and about 495 nm. Region 714 may not exhibit an increase in absorption coefficient. Region 716 may exhibit an increase in absorption coefficient in a wavelength range from about 570 nm to about 590 nm.

As illustrated, the different regions may be sorted or categorized into different bins or categories based on the different optical property(s) (e.g., change in optical property(s). The structure 700 may be modified (e.g., cut) to form one or more optical devices 722 of a first type or category from the first region 712. The structure 700 may be modified (e.g., cut) to form one or more optical devices 724 of a second type or category from the second region 714. The structure 700 may be modified (e.g., cut) to form one or more optical devices 726 of a third type or category from the third region 716.

The optical devices may be formed from any suitable region or section of the structure 700 by cutting or modifying the structure 700 along any direction. For instance, FIG. 8G depicts horizontal cutting of the structure 700 to form different optical devices 722, 724, and 726. FIG. 8H depicts in dashed line generally vertical cutting of the structure 700 to form optical devices 730. FIG. 8I depicts in dashed line generally angled (e.g., between about 15° and about 65° relative to the top surface) cutting of the structure to form optical devices 730.

FIG. 8J depicts in dashed line cutting of the structure 700 to form optical devices of different shapes. For instance, the structure 700 may be cut or modified to form a first optical device 732 having a first shape and a second optical device 734 having a second shape. The shapes may include any number of surfaces, such as concave surfaces, convex surfaces, linear surfaces, curved surfaces, non-linear surfaces, stepped surfaces, textured surfaces (e.g., to provide different optical responses), grated surfaces, angled surfaces, irregular surfaces, etc. without deviating from the scope of the present disclosure.

FIG. 8K depicts in dashed line cutting of the structure 700 along many different orientations and shapes to form optical devices. For instance, the structure 700 may be cut or modified in a first orientation to provide optical device 740. The structure 700 may be cut or modified in a second orientation to provide optical device 742. The structure 700 may be cut or modified in a third orientation to provide optical device 744. The structure 700 may be cut or modified in a fourth orientation to provide optical device 746. Each of the optical devices 740, 742, 744, 746 may have different shapes, optical properties, may be associated with cuts along different crystal planes, may have different shaped surfaces. The shapes of the optical devices 740, 742, 744, 746 may be modified before or after separation from the structure 700.

Those of ordinary skill in the art, using the disclosures provided herein, will understand that devices may be cut, modified, and/or removed from the structure 700 along any crystal plane, across crystal planes, between crystal planes, off-axis to crystal planes, etc. The devices may be cut in any shape or form. The cut lines to separate the optical devices may be linear, curved, non-linear, irregular, etc.

In some embodiments, the devices may be processed to include a coating (e.g., a reflective coating, anti-reflective coating, diffusive coating, filter coating, protective coating, etc.). The devices may be processed to have a textured or grated surface, or other surface to provide a desired optical effect (e.g., diffusion, scattering, transmission, etc.). In some embodiments, the surface of any of the devices or structures provided herein may be modified (e.g., using implant, surface processing (e.g., grinding, lapping, polishing), laser, etching, etc.) to modify the optical properties of the surface of the device.

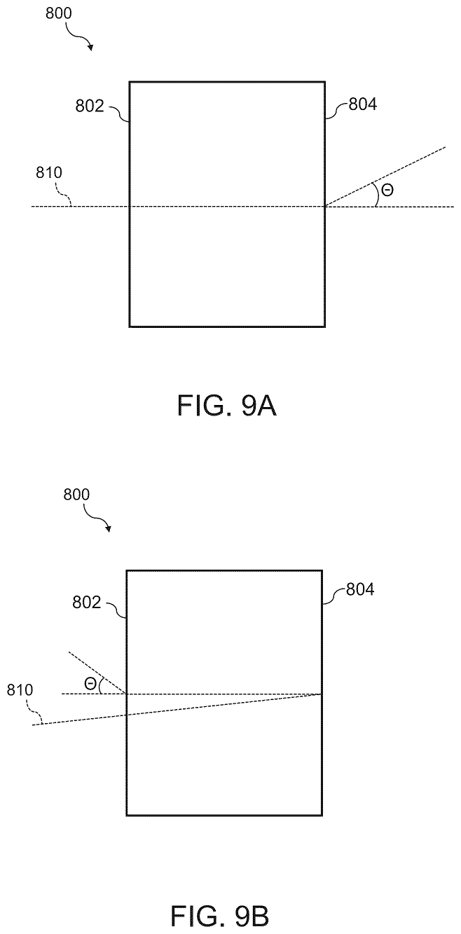

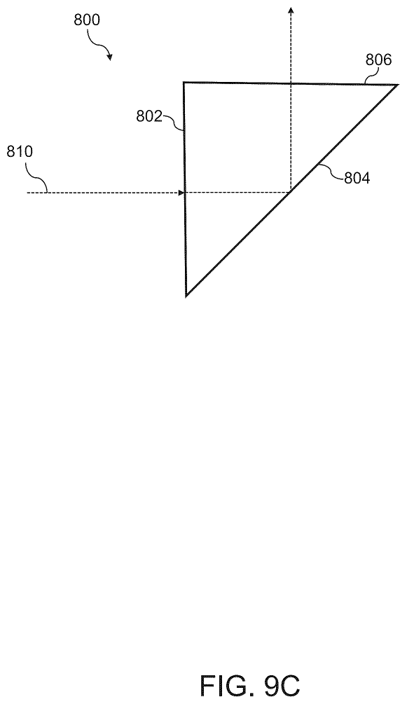

FIGS. 9A-9C depict example silicon carbide crystalline material structures 800 acting as optical devices according to example embodiments of the present disclosure. Each of the optical structures 800 may have one or more of the properties of any of the silicon carbide crystalline material structures described herein.

For instance, in some embodiments, the crystalline material structures 800 may have a first absorption coefficient that is less than about 0.15 cm⁻¹ over a wavelength range from about 420 nm to about 700 nm along a c-axis of the crystalline material. The structures 800 may exhibit a change in a second absorption coefficient along an axis generally perpendicular to the c-axis when illuminated with polarized light along the axis generally perpendicular to the c-axis. The structures 800 may have a second absorption coefficient that is defined by a minimum value and a maximum value that are about 0.15 cm⁻¹ apart over a wavelength range from about 420 nm to about 700 nm along a second axis generally perpendicular to the c-axis of the crystalline material.

In the example of FIG. 9A, the structure 800 may have a first surface 802 and an opposing second surface 804. In FIG. 9A, the first surface 802 and the second surface 804 may be generally parallel. However, in other embodiments, the first surface 802 and the second surface may not be generally parallel. The crystalline material of the structure 800 may have one or more optical properties (e.g., absorption, transmissivity, refractive index, waveguide efficiency, etc.) such that electromagnetic radiation 810 having a wavelength range of from about 380 nm to about 1200 nm entering the first surface 802 and exiting the second surface 804 with a beam divergence θ of less than about 10°, such as less than about 5°, such as less than about 1°. In some embodiments, the crystalline material of the structure 800 may have one or more optical properties (e.g., absorption, transmissivity, waveguide efficiency, refractive index, etc.) such that electromagnetic radiation 810 having a wavelength range of from about 380 nm to about 700 nm entering the first surface 802 and exiting the second surface 804 with a beam divergence θ of less than about 10°, such as less than about 5°, such as less than about 1°.

In the example of FIG. 9B, the structure 800 may have a first surface 802 and an opposing second surface 804. In FIG. 9B, the first surface 802 and the second surface 804 may be generally parallel. However, in other embodiments, the first surface 802 and the second surface may not be generally parallel. The structure 800 of FIG. 9B is similar to that of FIG. 9A, except that the second surface 804 has reflective properties. More particularly, electromagnetic radiation 810 in a wavelength range from about 380 nm to about 1200 nm, entering the first surface 802 and being reflected from the second surface 804 to exit the first surface 802 with a beam divergence θ of less than about 10°, such as less than about 5°, such as less than about 1°. In some embodiments, electromagnetic radiation 810 having a wavelength range of from about 380 nm to about 700 nm entering the first surface 802 is reflected from the second surface 804 and exits the first surface 802 with a beam divergence θ of less than about 10°, such as less than about 5°, such as less than about 1°.

In the example of FIG. 9C, the structure 800 may have a first surface 802, a second surface 804, and a third surface 806. The structure 800 of FIG. 9C is similar to that of FIG. 9B. However, in FIG. 9C the second surface 804 is oriented such that electromagnetic radiation 810 in a wavelength range from about 380 nm to about 1200 nm is reflected from the second surface 804 and exits the third surface 806. In some embodiments, the second surface 804 is oriented such that electromagnetic radiation 810 in a wavelength range from about 380 nm to about 1200 nm is reflected from the second surface 804 and exits the third surface 806.

FIGS. 9A-9C depict example optical devices for purposes of illustration and discussion. Those of ordinary skill in the art, using the disclosures provided herein, will understand that many different optical devices having various characteristics are within the scope of the present disclosure.

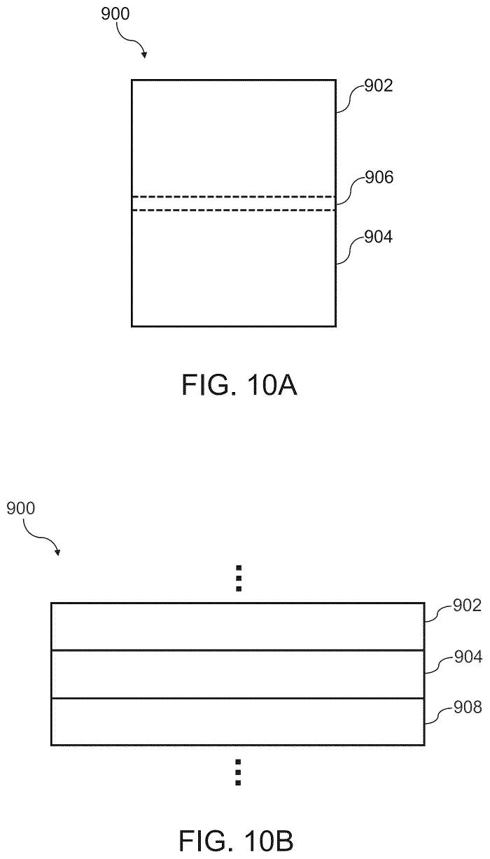

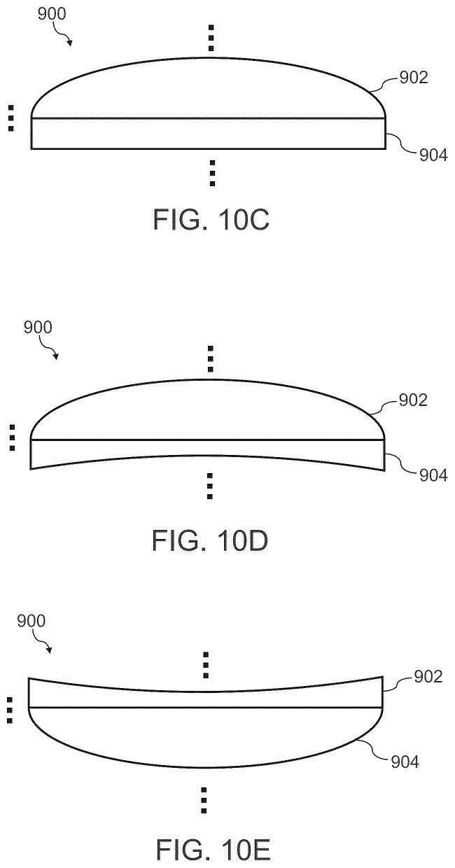

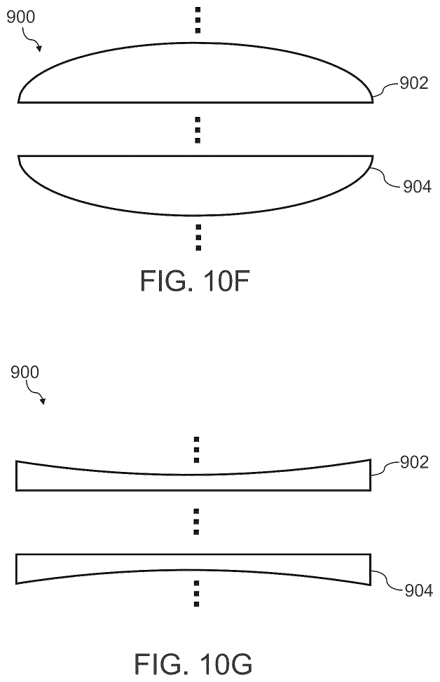

Any of the structures disclosed in the present disclosure may be a single piece or may be formed from multiple structures that are bonded, adhered, coupled or otherwise provided together. For instance, FIG. 10A depicts a multipiece crystalline material structure 900 (e.g., composite structure) according to example aspects of the present disclosure. The crystalline material structure 900 may include a first structure 902. The first structure 902 may exhibit any of the properties of the silicon carbide crystalline material structures provided herein.

For instance, in some embodiments, the first structure 902 may have a first absorption coefficient that is less than about 0.15 cm⁻¹ over a wavelength range from about 420 nm to about 700 nm along a c-axis of the crystalline material. The first structure 902 may exhibit a change in a second absorption coefficient along an axis generally perpendicular to the c-axis when illuminated with polarized light along the axis generally perpendicular to the c-axis. The first structure 902 may have a second absorption coefficient that is defined by a minimum value and a maximum value that are about 0.15 cm⁻¹ apart over a wavelength range from about 420 nm to about 700 nm along a second axis generally perpendicular to the c-axis of the crystalline material. In some embodiments, the first structure 902 may include a notch absorption coefficient in a subset of the wavelength range from about 420 nm to about 700 nm.

The crystalline material structure 900 may include a second structure 904 bonded, attached, coupled, or otherwise provided on the first structure 902. The second structure 904 may exhibit any of the properties of the silicon carbide crystalline material structures provided herein.

For instance, in some embodiments, the second structure 904 may have a first absorption coefficient that is less than about 0.15 cm⁻¹ over a wavelength range from about 420 nm to about 700 nm along a c-axis of the crystalline material. The second structure 904 may exhibit a change in a second absorption coefficient along an axis generally perpendicular to the c-axis when illuminated with polarized light along the axis generally perpendicular to the c-axis. The second structure 904 may have a second absorption coefficient that is defined by a minimum value and a maximum value that are about 0.15 cm⁻¹ apart over a wavelength range from about 420 nm to about 700 nm along a second axis generally perpendicular to the c-axis of the crystalline material. In some embodiments, the second structure 904 may include a notch absorption coefficient in a subset of the wavelength range from about 420 nm to about 700 nm.

In some embodiments, the first structure 902 and the second structure 904 are directly coupled together (e.g., using a direct bond, such as van der Waals forces). In some embodiments, the first structure 902 and the second structure 904 are coupled together using a bonding layer 906 (e.g., adhesive, attach material, etc.). The bonding layer 906 may have optical properties similar to that of the first structure 902 and the second structure 904 to preserve the optical characteristics of the overall structure 900. For instance, the bonding layer 906 may be an adhesive with about the same index of refraction as the first structure 902 and/or the second structure 904. The bonding layer may be an adhesive with a different index of refraction relative to the first structure 902 and/or the second structure 904.

In some embodiments, the composite silicon carbide crystalline material structure 900 may have any of the properties of the crystalline material structures provided herein. For instance, the structure 900 may have a first absorption coefficient that is less than about 0.15 cm⁻¹ over a wavelength range from about 420 nm to about 700 nm along a c-axis of the crystalline material. The structure 900 may exhibit a change in a second absorption coefficient along an axis generally perpendicular to the c-axis when illuminated with polarized light along the axis generally perpendicular to the c-axis. The structure 900 may have a second absorption coefficient that is defined by a minimum value and a maximum value that are about 0.15 cm⁻¹ apart over a wavelength range from about 420 nm to about 700 nm along a second axis generally perpendicular to the c-axis of the crystalline material. Alternatively, in some embodiments, the structure 900 may include a notch absorption coefficient in a subset of the wavelength range from about 420 nm to about 700 nm.

FIG. 10B depicts a multipiece crystalline material structure 900 (e.g., composite structure) according to examples of the present disclosure. The crystalline material structure 900 may have different portions with surfaces associated with different crystal planes. For instance, the crystalline material structure 900 may include a first structure 902, a second structure 904, and a third structure 908. As indicated by the ellipses, the structure 900 may include more or fewer structures without deviating from the scope of the present disclosure.

The first structure 902 may have a surface associated with, for instance, a first crystal plane (e.g., the c-plane). The second structure 904 may have a surface associated with, for instance, a second crystal plane (e.g., the m-plane). The third structure 908 may have a surface associated with a third crystal plane (e.g., off-axis to the c-plane). In this way, the composite structure 900 may include two or more structures with different crystal plane orientations.

In some embodiments, each structure 902, 904, and/or 908 may be associated with different optical properties or changes in optical properties. For instance, structure 902 may be associated with a first change in absorption coefficient when illuminated with polarized light along an axis generally perpendicular to the c-axis. The structure 904 may be associated with no change in absorption coefficient. The structure 908 may be associated with a different change in absorption coefficient relative to the structure 902. The structures 902, 904, and/or 908 may have different variations in optical properties. For instance, the structure 902 may have an absorption coefficient along a c-axis that is less than about 0.15 cm⁻¹ over a wavelength range from about 420 nm to about 700 nm along a c-axis of the crystalline material. However, structure 904 and/or structure 908 may have an absorption coefficient that is a notch absorption coefficient for a subset of wavelengths in the wavelength range from about 420 nm to about 700 nm along a c-axis of the crystalline material. In some embodiments, the first structure 902 may have the same index of refraction as the second structure 904 and/or the third structure 908. In some embodiments, the index of refraction of each of the first structure 902, the second structure 904, and the third structure 908 may be different.

In some embodiments, the multiple crystalline material structure 900 may include a plurality of structures each having a different shape. For instance, FIG. 10C depicts a multipiece crystalline material structure 900 that includes a first structure 902 having a first shape and a second structure 904 having a second shape. The first structure 902 includes a convex surface curving away from the second structure 904.

FIG. 10D depicts a multiple crystalline material structure 900 that includes a first structure 902 having a first shape and a second structure 904 having a second shape. The first structure 902 has a convex surface curving away from the second structure 904. The second structure 904 has a concave surface curving toward the first structure 902. As indicated by the ellipses, the structure 900 may include more or fewer structures without deviating from the scope of the present disclosure.

FIG. 10E depicts a multiple crystalline material structure 900 that includes a first structure 902 having a first shape and a second structure 904 having a second shape. The first structure 902 has a concave surface curving toward the second structure 904. The second structure 904 has a convex surface curving away from the first structure 902. As indicated by the ellipses, the structure 900 may include more or fewer structures without deviating from the scope of the present disclosure.

FIG. 10F depicts a multiple crystalline material structure 900 that includes a first structure 902 having a first shape and a second structure 904 having a second shape. The first structure 902 has a convex surface curving away from the second structure 904. The second structure 904 has a convex surface curving away from the first structure 902. As indicated by the ellipses, the structure 900 may include more structures between the first structure 902 and the second structure 904 without deviating from the scope of the present disclosure.

FIG. 10G depicts a multiple crystalline material structure 900 that includes a first structure 902 having a first shape and a second structure 904 having a second shape. The first structure 902 has a concave surface curving toward the second structure 904. The second structure 904 has a concave surface curving toward the first structure 902. As indicated by the ellipses, the structure 900 may include more structures between the first structure 902 and the second structure 904 without deviating from the scope of the present disclosure.

As demonstrated, the multipiece composite structure 900 according to example aspects of the present disclosure can include any combination of crystalline material structures having different orientations, surfaces, shapes, optical properties, or other characteristics without deviating from the scope of the present disclosure. The outer profiles of optical elements can be any shapes, profile and/or curvature (e.g., convex and concave), both flat, one flat and one concave or convex, combinations of shapes/profiles or more complex shapes/profiles (e.g., convex in middle and series of ridges around central convex portion, the same and/or different thicknesses and/or the same, similar and/or different optical properties. A composite lens can include an optical device as part of outer optical element or sandwiched optical elements.

In some embodiments, the structures 900 may be processed to include a coating (e.g., a reflective coating, anti-reflective coating, diffusive coating, filter coating, protective coating, etc.). In some embodiments, the structures 900 may be processed to have a textured or grated surface or other surface to provide a desired optical effect (e.g., diffusion, scattering, transmission, etc.).

As indicated by the ellipses in FIGS. 10A-10G, the composite structures 900 may include additional structures without deviating from the scope of the present disclosure. The additional structures may or may not be silicon carbide crystalline material. For instance, the additional structure may be, for instance, glass, polycarbonate, plastic, sapphire, or other suitable material. In addition, although the composite structures 900 of FIGS. 10A-10G are discussed with reference to both a first structure 902 and a second structure 904 being silicon carbide crystalline material, one of the first structure 902 or second structure 904 may be silicon carbide crystalline material with the other structure being a different material. For instance, in some embodiments, the composite optical structure can just have the displayed elements with optically matched index of refraction relationship with the other optical elements. Additional coatings and/or optical elements (such as silicon carbide based optical elements or optical elements made of different materials) can be included as indicated by the three dots in the figures.

In some embodiments, any of the structures described herein may be processed to include additional layers, such as a coating (e.g., reflective coatings, anti-reflective coatings, diffusive coatings, filter coatings, etc.). In some embodiments, any of the structures provided herein may include an epitaxial layer (e.g., epitaxial silicon carbide) provided on the structure. For instance, in some embodiments, the structure may be processed (e.g., sliced) to form a wafer or substrate. An epitaxial layer may be formed on the wafer or substrate. The epitaxial layer may have similar optical properties to the wafer or substrate, or may have different optical properties.

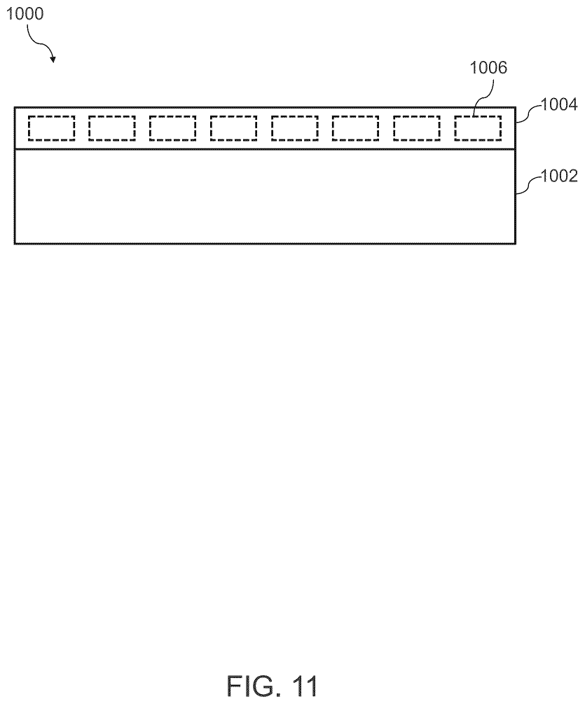

FIG. 11 depicts a cross-sectional view of an example device 1000 may include a substrate 1002 formed from one of the structures described in the present disclosure. The structure may exhibit one or more of the optical properties of the structures described in the present disclosure.

For instance, in some embodiments, the substrate 1002 may have a first absorption coefficient that is less than about 0.15 cm⁻¹ over a wavelength range from about 420 nm to about 700 nm along a c-axis of the crystalline material. The substrate 1002 may exhibit a change in a second absorption coefficient along an axis generally perpendicular to the c-axis when illuminated with polarized light along the axis generally perpendicular to the c-axis. The substrate 1002 may have a second absorption coefficient that is defined by a minimum value and a maximum value that are about 0.15 cm⁻¹ apart over a wavelength range from about 420 nm to about 700 nm along a second axis generally perpendicular to the c-axis of the crystalline material. In some embodiments, the substrate 1002 may include a notch absorption coefficient in a subset of the wavelength range from about 420 nm to about 700 nm. The substrate 1002 may have a thickness in a range of about 150 microns to about 700 microns, such as about 150 microns to about 500 microns, such as about 200 microns to about 350 microns.

The epitaxial layer 1004 may be epitaxially formed silicon carbide. In some embodiments, the epitaxial layer 1004 may have similar optical properties to the substrate 1002. However, in some embodiments, the epitaxial layer 1004 may have different optical properties. In some embodiments, a surface of the epitaxial layer 1004 may be modified (e.g., using implant, surface processing (e.g., grinding, lapping, polishing), laser, etching, etc.) to modify the optical properties and/or for doping.

In some embodiments, different regions of the epitaxial layer 1004 may be doped (e.g., using implantation, epitaxial growth of doped materials, etc.) to form devices 1006 in the epitaxial layer 1004. The devices 1006 can be any suitable device (e.g., such as a lateral MOSFET or other lateral device). In some embodiments the devices 1006 may be optically controlled devices. For instance, in some embodiments, portions of the devices 1006 may include regions that exhibit a change in optical property when exposed to polarized light. Taking advantage of this change, the devices 1006 may use polarized lighting for gating of various optical effects to provide an optically controlled device (e.g., controlled or modified by polarized light). In some embodiments, the devices may be optically transparent and operate in the optical path.

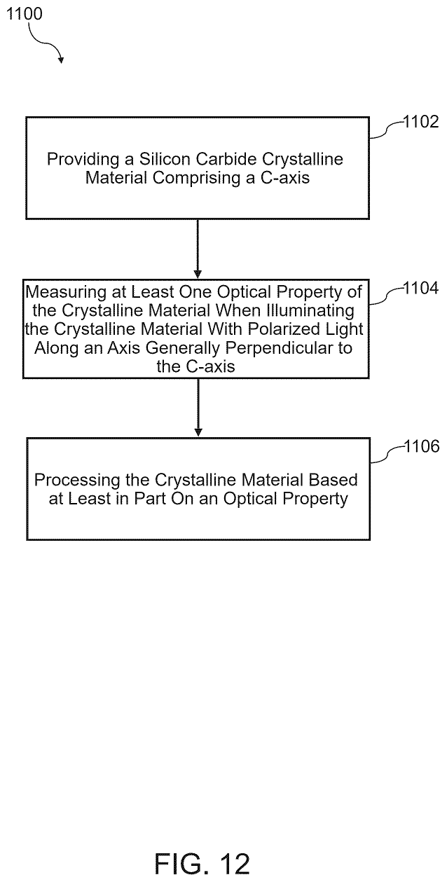

FIG. 12 depicts a flow chart of an example method 1100 according to example aspects of the present disclosure. FIG. 12 depicts example process operations for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 1102, the method 1100 includes providing a silicon carbide crystalline material structure. The silicon carbide crystalline material structure can include any of the silicon carbide crystalline material structures described herein. In some embodiments, the silicon carbide crystalline material has a c-axis. The crystalline material may have various physical properties, including, for instance, an outer diameter in a range of about 100 mm to about 400 mm. Additionally, in some embodiments, the crystalline material may include a thickness along the c-axis in a range of about 10 mm to about 200 mm, such as about 10 mm to about 60 mm, such as about 10 mm to about 50 mm. The crystalline material may include one or more of 4H silicon carbide, 6H silicon carbide, semi-insulating silicon carbide, n-type silicon carbide, or p-type silicon carbide.

Additionally, in some embodiments, the crystalline material may include an absorption coefficient along the c-axis that is less than about 0.15 cm⁻¹ over a wavelength range from about 420 nm to about 700 nm. Alternatively, in some embodiments, the crystalline material may include a notch absorption coefficient in a subset of the wavelength range from about 420 nm to about 700 nm.

The crystalline material may also include a variety of structures. For instance, in various embodiments, the crystalline material may be a preform, workpiece, boule, ingot, or wafer. The crystalline material may be used to form an optical device, such as a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device. The crystalline material may also be a combination of multiple structures, such as a first structure coupled to a second structure. In some embodiments, the crystalline material may include a window on at least one surface. The window may have a surface roughness in a range of about 0.5 nm to about 100 nm.

At 1104, the method 1100 includes measuring at least one optical property of the crystalline material (e.g., change in optical property) when illuminating the crystalline material with polarized light along an axis generally perpendicular to the c-axis. In some embodiments, the polarized light may be linearly polarized with a polarization direction that is generally perpendicular or generally parallel to the c-axis. As an example, the optical property may include an absorption coefficient in wavelength range of about 420 nm to about 700 nm.

The optical property of the crystalline material (e.g., change in optical property) encompasses a variety of different measurable characteristics across various wavelengths. For instance, in some embodiments, the optical property may include an increase in the absorption coefficient in a wavelength range from about 450 nm to about 495 nm when illuminated with linearly polarized light along the axis generally perpendicular to the c-axis. Alternatively, the optical property may be a lack of increase in absorption coefficient in the wavelength range from about 450 nm to about 495 nm.

In some embodiments, the crystalline material may include multiple regions where each region has different optical property(s) (e.g., changes in optical property(s)). As an example, the crystalline material may include a first region that exhibits an increase in absorption coefficient between about 450 nm and about 495 nm and/or a second region that does not exhibit an increase in absorption coefficient between about 450 nm and about 495 nm. In these embodiments, the region exhibiting an increase between about 450 nm and about 495 nm may include a higher nitrogen or other dopant concentration compared to other regions. As another example, in some embodiments, the change in optical property for a region may include an increase in the absorption coefficient in a wavelength range from about 570 nm to about 590 nm when illuminated with linearly polarized light along the axis generally perpendicular to the c-axis. In these embodiments, the region exhibiting an increase between about 570 nm and about 590 nm may include a lack of nitrogen dopants and/or higher p-type dopant concentration compared to other regions. In some embodiments, a region may not exhibit any change in optical property when illuminated with polarized light. In this example, the region may be an electrically compensated region of the silicon carbide crystalline material.

At 1106, the method 1100 includes processing the crystalline material based at least in part on the optical property (e.g., change in optical property). Processing the crystalline material may include a variety of operations and/or steps. For instance, processing the crystalline material may include modifying, sorting, inspecting, and/or evaluating the crystalline material based on the change in an optical property. As an example, one or more physical properties of the crystalline material may be modified based on the optical property (e.g., change in optical property). Physical properties may include shape, thickness, diameter, edge count, or surface count.

Additionally, as an example, the crystalline material may be sorted into a group of crystalline workpieces based on the change in optical property. Additionally, in some embodiments, a surface of the crystalline material may be inspected for one or more defects or a dopant concentration of at least a portion of the crystalline material may be evaluated based on the change in the optical property. In some embodiments, the crystalline material may be evaluated, inspected, and/or analyzed for polytype inclusions and/or polytype transitions. In some embodiments, the crystalline material may be evaluated, inspected, and/or analyzed for foreign material inclusions and/or voids. Other suitable operations may be performed on the crystalline material structure based at least in part on the change in optical property without deviating from the scope of the present disclosure.

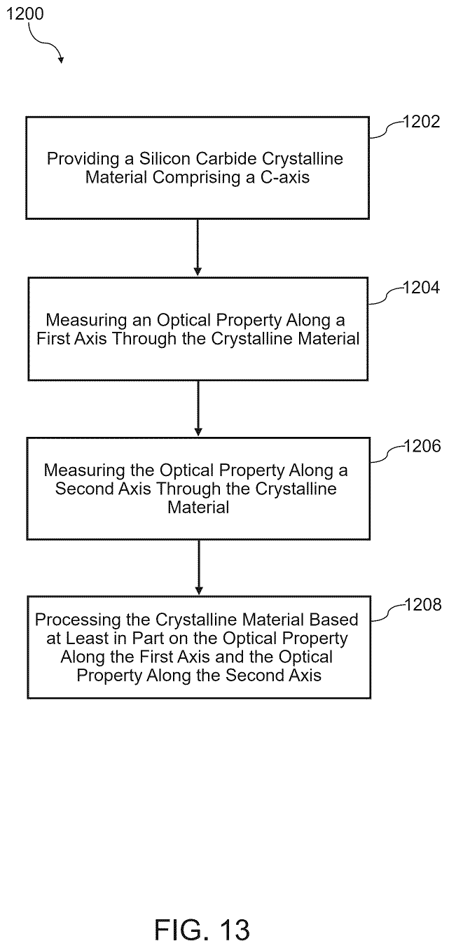

FIG. 13 depicts a block diagram of a method 1200 according to example aspects of the present disclosure. FIG. 13 depicts example process operations for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 1202, the method 1200 includes providing a silicon carbide crystalline material structure. The silicon carbide crystalline material structure can include any of the silicon carbide crystalline material structures described herein. In some embodiments, the silicon carbide crystalline material has a c-axis. For instance, the crystalline material may have various physical properties, including, for instance, an outer diameter in a range of about 100 mm to about 400 mm. Additionally, in some embodiments, the crystalline material may include a thickness along the c-axis in a range of about 10 mm to about 200 mm, such as about 10 mm to about 60 mm, such as about 10 mm to about 50 mm. The crystalline material may include one or more of 4H silicon carbide, 6H silicon carbide, semi-insulating silicon carbide, n-type silicon carbide, or p-type silicon carbide.

Additionally, in some embodiments, the crystalline material may include an absorption coefficient along the c-axis that is less than about 0.15 cm⁻¹ over a wavelength range from about 420 nm to about 700 nm. Alternatively, in some embodiments, the crystalline material may include a notch absorption coefficient in a subset of the wavelength range from about 420 nm to about 700 nm.

The crystalline material may also include a variety of structures. For instance, in various embodiments, the crystalline material may be a preform, workpiece, boule, ingot, or wafer. The crystalline material may be used to form an optical device, such as a lens, window, waveguide, Fresnel lens, prism, collimator, beam splitter, grating, polarizer, optical waveguide, filter (e.g., high pass filter, low pass filter, notch filter, bandpass filter, edge filter, etc.), light multiplexer, optical amplifier and/or modulator, refractor, or other optical device. The crystalline material may also be a combination of multiple structures, such as a first structure coupled to a second structure. In some embodiments, the crystalline material may include a window on at least one surface. The window may have a surface roughness in a range of about 0.5 nm to about 100 nm.

At 1204, the method 1200 includes measuring an optical property along a first axis through the crystalline material. As an example, the optical property may include an absorption coefficient in wavelength range of about 420 nm to about 700 nm. Measuring the optical property along the first axis encompasses a variety of different measurable characteristics across various wavelengths. However, the optical property may be any optical property described herein. For instance, the optical property may be one or more absorption properties, transmittance properties, reflectance properties, refractive index, dispersion, polarization, birefringence, opacity, scattering, fluorescence, phosphorescence, luminescence, etc.

At 1206, the method 1200 includes measuring the optical property along a second axis through the crystalline material. The second axis is different from the first axis. For instance, in one embodiment, the first axis is along a c-axis of the crystalline material and the second axis is along an axis generally perpendicular to the c-axis. In some embodiments the first axis is along a c-axis of the crystalline material and the second axis is at a non-perpendicular angle relative to the c-axis. In some embodiments, the first axis is perpendicular to the c-axis and the second axis is at a non-perpendicular angle to the first axis. In some embodiments, the first axis and the second axis are both at non-perpendicular angles relative to the c-axis. The optical property measured along the first axis may be the same or may be a different type of optical property relative to the optical property measured along the second axis.

Aspects of the present disclosure are discussed with reference to optical property measurements along two axes for purposes of illustration and discussion. Those of ordinary skill in the art, using the disclosures provided herein, will understand that measurement may be performed across more than two axes, such as three axes, four axes, five axes, six axes, seven axes or more, without deviating from the scope of the present disclosure.

At 1208, the method 1200 includes processing the crystalline material based at least in part on the optical property along the first axis and the optical property along the second axis. Processing the crystalline material may include a variety of operations and/or steps. For instance, processing the crystalline material may include modifying, sorting, inspecting, and/or evaluating the crystalline material based on the change in an optical property. As an example, one or more physical properties of the crystalline material may be modified based at least in part on the optical property along the first axis and the optical property along the second axis. Physical properties may include shape, thickness, diameter, edge count, or surface count.

Additionally, as an example, the crystalline material may be sorted into a group of crystalline workpieces based at least in part on the optical property along the first axis and the optical property along the second axis. Additionally, in some embodiments, the crystalline material may be inspected for one or more defects or a dopant concentration of at least a portion of the crystalline material may be evaluated based at least in part on the optical property along the first axis and the optical property along the second axis. In some embodiments, the crystalline material may be evaluated, inspected, and/or analyzed for polytype inclusions and/or polytype transitions. In some embodiments, the crystalline material may be evaluated, inspected, and/or analyzed for foreign material inclusions and/or voids. Other suitable operations may be performed on the crystalline material structure based at least in part on the optical property along the first axis and the optical property along the second axis. without deviating from the scope of the present disclosure.

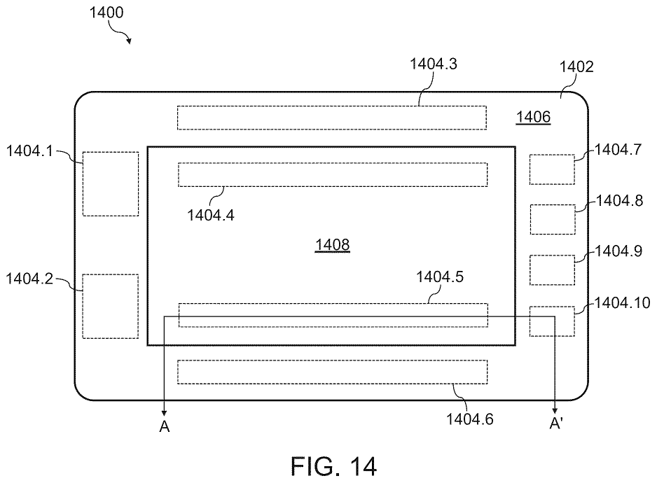

In some examples, the crystalline material according to examples of the present disclosure may be used as waveguides or other optical devices (e.g., lenses) in virtual reality and/or augmented reality applications. FIGS. 14-19 depict example optical devices that incorporate crystalline material according to examples of the present disclosure.

FIG. 14 depicts a crystalline material (e.g., silicon carbide) optical device 1400 (e.g., lens) according to example embodiments of the present disclosure. The optical device 1400 may include silicon carbide crystalline material having optical properties according to examples of the present disclosure. The silicon carbide crystalline material may act as a waveguide for use in, for instance, providing visual displays in virtual reality and/or augmented reality applications (e.g., in a virtual reality headset or augmented reality headset). A single optical device 1400 is depicted in FIG. 14, however, those of ordinary skill in the art, using the disclosures provided herein, will understand that the lens could comprise multiple separate optical devices (e.g., two separate lenses, three separate lenses, etc.) without deviating from the scope of the present disclosure.

The optical device 1400 may comprise a crystalline material waveguide 1402 (e.g., silicon carbide crystalline material waveguide) according to examples of the present disclosure. The optical device 1400 may be formed from a preform or other workpiece according to examples of the present disclosure. For instance, the optical device 1400 may be an optical device formed from a structure 700 as illustrated in FIGS. 8A-8K. The optical device 1400 may have any shape.

In some examples, the optical device 1400 may be configured to display optical information as a visual display to a user. The optical information may be a visual display. In some embodiments, the optical device 1400 may include a plurality of different display input or output areas 1404.1, 1404.2, 1404.3, 1404.4, 1404.5, 1404.6, 1404.7, 1404.8, 1404.9, 1404.10, . . . 1404.n to provide the visual displays or images or other light into or out of the optical device 1400. The input or output areas 1404.1, 1404.2, 1404.3, 1404.4, 1404.5, 1404.6, 1404.7, 1404.8, 1404.9, 1404.10, . . . 1404.n may be provided anywhere on the optical device 1400 without deviating from the scope of the present disclosure.

In some embodiments, the optical device 1400 may include a first portion 1406 and a second portion 1408. The first portion 1406 may be a peripheral portion or side portion of the optical device 1400. The second portion 1408 may be a center portion of the optical device 1400 in near view of a user. The second portion 1408 may be directly in view of a user of a device including the optical device 1400. The first portion 1406 may be in peripheral view of a user of a device including the optical device 1400.

In some embodiments, the first portion 1406 is opaque to external light (e.g., includes one or more coatings, films, or structures to block light). The second portion 1408 may allow external light to transmit through the optical device 1400 (e.g., for use in augmented reality applications). However, other configurations are possible. For instance, the first portion 1406 and the second portion 1408 may be opaque to external light. The first portion 1406 and the second portion 1408 may be transparent to external light. The first portion 1406 may be transparent to outside light and the second portion 1408 may be opaque to external light.

The optical signals for the visual displays may be coupled into the optical device 1400 which acts as a waveguide 1402 for the optical signals. The optical signals may be provided from a light source, such as a projector or other light source. The projector or light source may be, for instance, a light emitting diode (LED) or micro-LED display, OLED display, liquid crystal display (LCD), quantum dot display, or other suitable display. The optical signals may be white light, single or multiple colors or wavelengths, red, green blue (RGB) optical signals, or other optical signal/combination of optical signals. The optical signals may propagate through the optical device 1400 to the various visual displays at least in part using internal reflection through the optical device 1400. Various couplers and/or waveguiding features (e.g., input couplers, output couplers, dividers, reflectors, anti-reflective internal features or surfaces) may be used to couple the light signals into and out of the optical device 1400. In some embodiments, the light source may provide light signals of different wavelengths at different locations into the waveguide 1402. For instance, the red, green, and blue elements of a full display may be coupled into the waveguide from separate proximate input coupler locations and combined to form a full RGB image at an output coupling for display to a user.

Input couplers may be structures that are used to input light into the optical device 1400 such that the electromagnetic radiation is at least partially propagated through the optical device 1400 (e.g., using internal reflection) as a waveguide. Output couplers may cause electromagnetic radiation propagating through the optical device 1400 to exit, be output from, or be transmitted through a surface of the optical device 1400 as, for instance, a visual display.

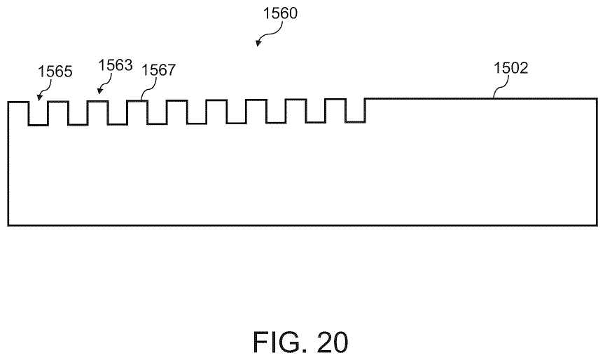

Various structures may be used as input couplers and/or output couplers. For instance, input couplers and output couplers may include, for instance, one or more gratings, Bragg gratings, surface-relief gratings, diffractive optical elements, prism couplers, tapered structures, end-fire couplings, branch couplers (e.g., multi-branch couplers, Y-branch couplers), directional couplers, textured surface(s), or other suitable structures. The input couplers and output couplers may be separate structures that are on the optical device 1400 or may be an integral part of the optical device 1400. For instance, in some examples, the input couplers and/or output couplers may include modified portions of the optical device 1400 itself, such as gratings or surface textures integrated into the surface using a surface processing operation (e.g., wire saw, laser-based surface processing operation, grinding, wet etching, dry and/or plasma etching, etc.). For instance, an input coupler and/or an output coupler may be a laser defined structure in the material of the optical device 1400. In some examples, incorporation of input couplers and output couplers may be implemented using techniques suitable for modifying hard materials, such as silicon carbide, such as laser-based surface processing operations. An example coupler is discussed with reference to FIG. 20.

In some examples, the optical device 1400 may include one or more input couplers (e.g., a plurality of input couplers) and/or one or more output couplers (e.g., output couplers) on a major surface, edge surface, multiple surface, etc. The optical device 1400 may include one or more coatings, films, or other structures to assist with internal reflection of light through the optical device 1400 and/or to block external light, allow external light to be transmitted through the optical device 1400, or provide other optical functions (e.g., antireflective properties, polarization, etc.).

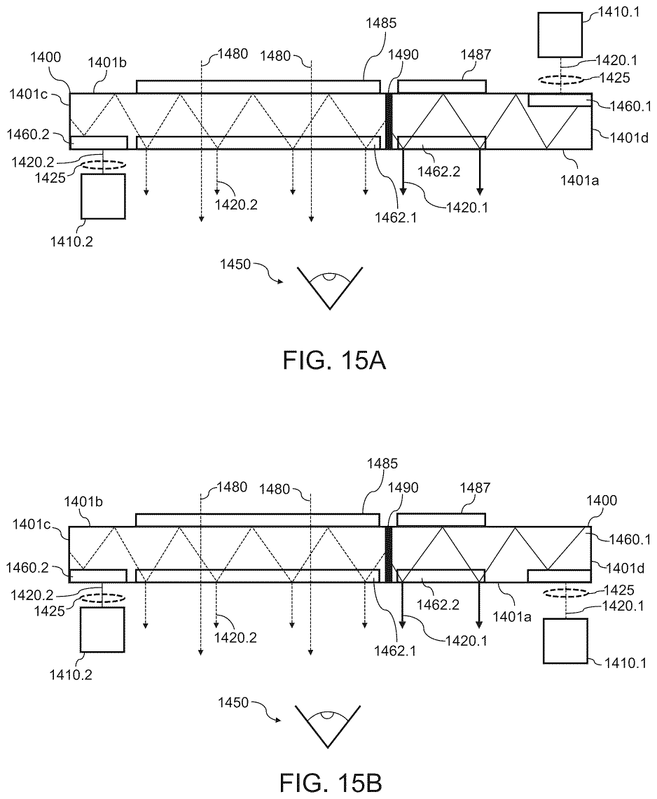

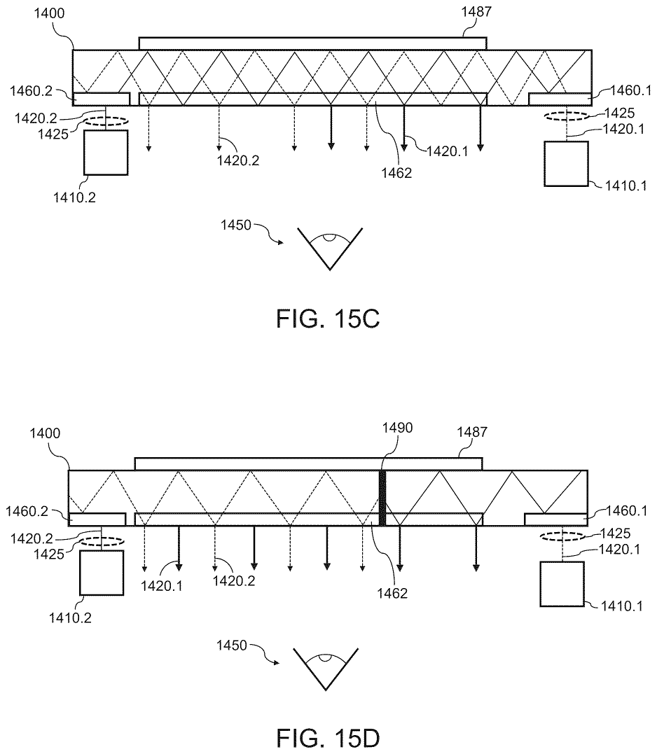

For instance, FIG. 15A depicts a cross-sectional view of the optical device 1400 along, for instance line A-A′ of FIG. 14. The cross-sectional view of FIG. 15A depicts one example configuration of the optical device 1400 for use in an augmented reality application. The optical device 1400 includes multiple display inputs coupled into a waveguide (e.g., the optical device 1400) from respective input couplers and displayed in multiple display zones. For instance, a light 1420.1 (e.g., an image) from a light source 1410.1 (e.g., projector or display) is coupled into the waveguide at input coupler 1460.1 and output from output coupling 1462.2 in a first zone such that the light 1420.1 is output as a first visual display to be viewed by a user 1450. A light 1420.2 (e.g., an image) from a second light source 1410.2 (e.g., projector or display) is coupled into the waveguide at input coupler 1460.2 and output from output coupling 1462.1 to be displayed to the user 1450 from a second zone such that the light 1420.2 is output as a second visual display to be viewed by a user 1450. The first visual display may be spatially separated from the second visual display. In the example of FIG. 15A, external light 1480 (e.g., from the outside world or environment) is also output from the output coupling 1462.1 along with the light (e.g., image) from the second display 1410.2 such that the image is superimposed with the user's view of the outside world. As discussed below, an optical divider 1490 or other light guiding elements may be used to divide the various display zones In some embodiments, light sources that are configured to form an RGB image may use separate R, G and B light sources that are coupled into the waveguide at different yet proximate input couplers that are recombined in the waveguide/output coupling so that the image is viewed by the user.

More particularly, FIG. 15A depicts how light propagates through the silicon carbide material 1402 of the optical device 1400 using internal reflection. More particularly, the optical device 1400 may include a first major surface 1401a, a second major surface 1401b, and edge surface(s) 1401c, 1401d. In some examples, an edge surface 1401c, 1401d has less surface area relative to a major surface 1401a, 1401b. In some examples, an edge surface 1401c, 1401d has at least 10 times less surface area than a major surface 1401a, 1401b, such as 20 times less, such as in a range of 10 times less to about 30 times less or even less depending on the application.

A first light source 1410.1 (e.g., projector or display) may provide light signal 1420.1 (e.g., white light, red, green, and/or blue light, image, etc.) to a first input coupler 1460.1. The first input coupler 1460.1 may be on major surface 1401b of the optical device 1400. A second light source 1410.2 (e.g., projector or display) may provide light signal 1420.2 (e.g., white light, red, green, and/or blue light, image, etc.) to a second input coupler 1460.2. The second input coupler 1460.2 may be on a different major surface 1401a of the optical device 1400 relative to the first input coupler 1460.1. However, the first input coupler 1460.1 and the second input coupler 1460.2 may be on the same surface without deviating from the scope of the present disclosure as illustrated in FIG. 15B.

In some examples, an optional optical device 1425 (e.g., magnifying lens, demagnifying lens, collimator, filter, prism, etc.) may be in the optical path between the one or more light sources 1410.1, 1410.2 and the input coupler 1460.1, 1460.2. The optical device 1425 may condition the light signals 1420.1, 1420.2. In some embodiments, the optical device 1425 may be a magnifying lens, demagnifying lens, collimator, filter, prism, etc.

The first light signal 1420.1 (e.g., white light, red, green, and/or blue light, or image) may propagate through the optical device 1400 and exit the optical device 1400 at output coupling 1462.2 to provide one or more visual displays to a user 1450. The second light signal 1420.2 may propagate through the optical device 1400 and exit the optical device 1400 at output couplings 1462.1 to provide one or more visual displays to the user 1450. The output coupling 1462.1 may be for a first display area on the optical device 1400. The output coupling 1462.2 may be for a second display area. For instance, the output coupling 1462.1 may be for a display area in a center portion for direct display to a user. The output coupling 1462.1 may be for a display area in a peripheral portion of the optical device 1400. In some embodiments, the output couplings 1462.1, 1462.2 may be selective such that the output coupling for the first light may be different from the output coupling for the second light.

As illustrated, the optical device 1490 may include a divider 1490. The divider 1490 may be a structure (e.g., opaque structure, reflective structure) that prevents further propagation of light using internal reflection through the workpiece 1400. The divider 1490 may divide the workpiece 1402 into multiple display zones. In some embodiments, the divider 1490 may be a doped region or region with induced defects to prevent the further internal reflection of the light through the workpiece 1402.

In some examples, external light 1480 (e.g., from the external environment) may pass through the optical device 1400 so that a user 1450 may see beyond the optical device 1400 (e.g., in an augmented reality application). The optical device 1400 may include a coating, film, grating, coupling, or other structure 1485 to facilitate transmission of the external light 1480 through the optical device 1400. In some embodiments, the optical device may include a coating, film, or other structure 1487 to block external light through portions of the optical device 1400. For instance, the optical device 1400 may be transparent to external light in a central portion of the optical device 1400. However, the optical device 1400 may be opaque to external light in a peripheral portion of the optical device 1400.

FIG. 15B depicts a cross-sectional view of the optical device 1400 in a configuration similar to that of FIG. 15A. However, in FIG. 15B, the first light source 1410.1 and the second light source 1410.2 provide light to a same major surface 1401a of the optical device 1400. The input coupler 1460.1 and the input coupler 1460.2 are on the same major surface 1401a of the optical device 1400.

FIG. 15C depicts a cross-sectional view of the optical device 1400 in a configuration similar to that of FIG. 15A except for a virtual reality system rather than an augmented reality system. FIG. 15C depicts an embodiment having multiple light sources, (e.g., projectors or displays) that are coupled into the optical device 1400 and combined or superimposed in the waveguide and output from a single output coupler 1462. In addition, the optical device 1400 has a coating, film, or structure 1487 that is opaque to external light to block external light from transmitting through the optical device 1400 (e.g., for use in a virtual reality application).

FIG. 15D depicts an embodiment of an optical device 1400 for a virtual reality system with two light sources 1410.1 and 1410.2 (e.g., projectors or displays). For instance, light 1420.1 (e.g., an image) from a light source 1410.1 (e.g., projector or display) is coupled into the waveguide at input coupler 1460.1 and output from output coupling 1462.2 in a first zone to be viewed by a user 1450. Light 1420.2 (e.g., an image) from a second light source 1410.2 (e.g., projector or display) is coupled into the waveguide at input coupler 1460.2 and output from output coupling 1462.1 to be displayed to the user 1450 from a second zone. A divider 1490 or other optical structure may separate the optical device 1400 into the first zone and second zone. In some embodiments, the light source 1410.1 can be an image generated by a camera, e.g. to show the user an image or images of their surroundings in the outside world. The light source 1410.2 may provide light signals associated with the display of the virtual reality world.

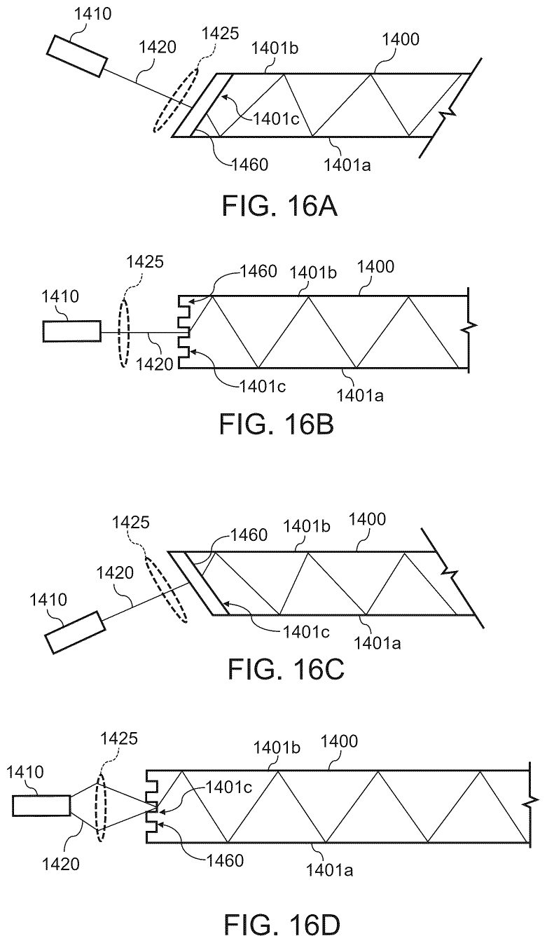

As discussed, the input couplers and/or the output couplers may be located on any surface of the optical device, including an edge surface of the optical device 1400. As an example, FIG. 16A depicts an example optical device 1400 having an input coupler 1460 on an edge surface 1401c of the optical device 1400. The edge surface 1401c may be an angled surface (e.g., not perpendicular to) relative to the major surface 1401a. The edge surface 1401c of FIG. 16A is at an acute angle relative to the major surface 1401a. The edge surface 1401c includes an input coupler 1460. The input coupler 1460 is configured to couple one or more light signals 1420 to the optical device 1400 such that the one or light signals 1420 propagate at least partially through the optical device 1400 using internal reflection. In some embodiments, the angled surface can include an input coupler comprised of grating in the edge surface 1401c.

FIG. 16B depicts an example optical device 1400 having an input coupler 1460 on an edge surface 1401c of the optical device 1400. The edge surface 1401c of FIG. 16B may be generally perpendicular to the major surface 1401a. The edge surface 1401c may include an input coupler 1460 that is a textured surface (e.g., a grating) formed in the optical device 1400. The input coupler 1460 is configured to couple one or more light signals 1420 to the optical device 1400 such that the one or more light signals 1420 propagate at least partially through the optical device 1400 using internal reflection.

FIG. 16C depicts an example optical device 1400 having an input coupler 1460 on an edge surface 1401c of the optical device 1400. The edge surface 1401c may be an angled surface (e.g., not perpendicular to) relative to the major surface 1401a. The edge surface 1401c of FIG. 16C is at an obtuse angle relative to the major surface 1401a. The edge surface 1401c includes an input coupler 1460. The input coupler 1460 is configured to couple one or more light signals 1420 to the optical device 1400 such that the one or light signals 1420 propagate at least partially through the optical device 1400 using internal reflection. In some embodiments, the angled surface can include an input coupler comprised of grating in the edge surface 1401c.

Various different optical devices 1425 may be used in conjunction with input couplers to couple light into the optical device 1400. For instance, as illustrated in FIG. 16D, an optical device 1425 (e.g., demagnifying lens) or other structure configured to decrease magnification of the light 1420 may be used in conjunction with the input coupler 1460 to couple light into the optical device 1400.

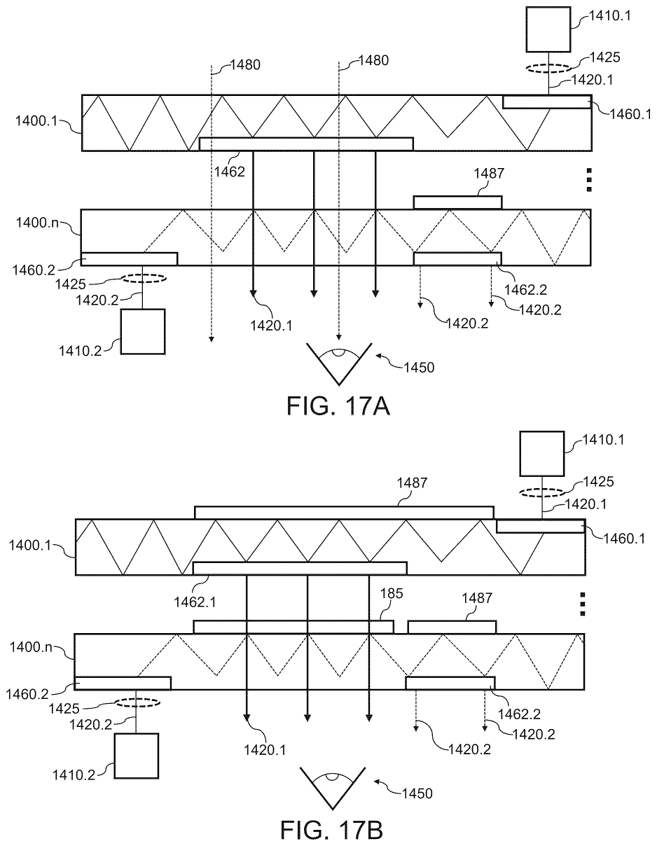

Aspects of the present disclosure may be used in optical devices incorporating multiple waveguide structures. For instance, FIG. 17A depicts a cross-sectional view of an example embodiment of an optical device that can be used for an augmented reality system having a plurality of waveguides 1400.1, . . . 1400.n. Two waveguides 1400.1 and 1400.n are illustrated in FIG. 17A where the first waveguide 1400.1 and second waveguide 1400.n are transmissive (e.g., see through) waveguides. Each waveguide has a light source 1410.1 and 1410.2 where external light (e.g., the view of the outside world) as well as the light from the light sources 1410.1 and 1410.2 are output for the user. Those of ordinary skill in the art, using the disclosures provided herein, will understand that the system may include any number of waveguides 1400.1, . . . 1400.n without deviating from the scope of the present disclosure.

A first light source 1410.1 (e.g., projector) may provide light signal 1420.1 to the first waveguide 1400.1 through a first input coupler 1460.1. The light signal 1420.1 may propagate at least partially through the waveguide 1400.1 using internal reflection. The light signal 1420.1 may exit the first waveguide 1400.1 through an output coupler 1462.1 and may be transmitted through a second optical device 1400.n to a user 1450.

A second light source 1410.2 (e.g., projector) may provide light signal 1420.2 to the second optical device 1400.n through a second input coupler 1460.2. The light signal 1420.2 may propagate at least partially through the optical device 1400.n using internal reflection. The light signal 1420.2 may exit the second optical device 1400.n through an output coupler 1462.2 and may be provided for visual display to the user 1450 in the same or different display zone relative to the light 1420.1. External light 1480 may pass through both the first waveguide 1400.1 and the second waveguide 1400.n (e.g., in augmented reality applications). In some embodiments, the second waveguide may include a coating, film, or structure 1487 or other structure to block external light from passing through at least a portion of the second waveguide 1400.n (e.g., in a portion corresponding to a display zone or an output coupler 1462.2 for the light 1410.2).

FIG. 17B depicts a cross-sectional view of an example embodiment having a plurality of optical devices 1400.1, . . . 1400.n. The embodiment of FIG. 17B may be suitable for use, in for instance, virtual reality applications. In FIG. 17B, the first waveguide 1400.1 may be opaque to external light. For instance, the waveguide 1400.1 may include a coating, film, or structure 1487 or other structure to block external light. The second waveguide 1400.n (and any additional waveguides) may be configured such that at least portions of the waveguide are transmissive (e.g., see through) so as to be transparent to light, such as light from the first waveguide 1400.1, thereby allowing the user to see light output from other waveguides. For instance, a first portion of the second waveguide 1400.n may include a coating 185 or other structure that allows light from the first waveguide 1400.1 to be transmitted through the second optical device 1400.n to a user 1450. However, a second portion of the second waveguide 1400.n may include a coating, film, or structure 1487 to block external light.

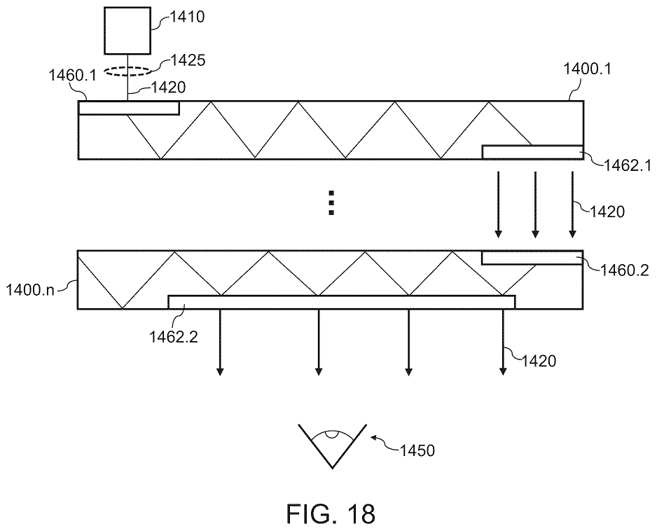

Other suitable configurations may be used without deviating from the scope of the present disclosure. For instance, FIG. 18 depicts an example embodiment having a plurality of waveguides 1400.1, . . . 1400.n. Two waveguides 1400.1, . . . 1400.n are illustrated in FIG. 18 for purposes of illustration and discussion. However, those of ordinary skill in the art, using the disclosures provided herein, will understand that the system may include any number of waveguides 1400.1, . . . 1400.n without deviating from the scope of the present disclosure.

As illustrated, one or more light sources 1410 may provide one or more light signals 1420 to a first input coupler 1460.1 on a first waveguide 1400.1. The one or more light signals 1420 may propagate through at least a portion of the first waveguide 1400.1 (e.g., using internal reflection) and may exit the first workpiece 1400.1 at a first output coupler 1462.1.

The one or more light signals 1420 may be provided to a second input coupler 1460.2 on a second waveguide 1400.n. The one or more light signals 1420 may propagate through at least a portion of the second waveguide 1400.n (e.g., using internal reflection) and may exit the second waveguide 1400.n at a second output coupler 1462.2 to a user 1450 as a visual display.

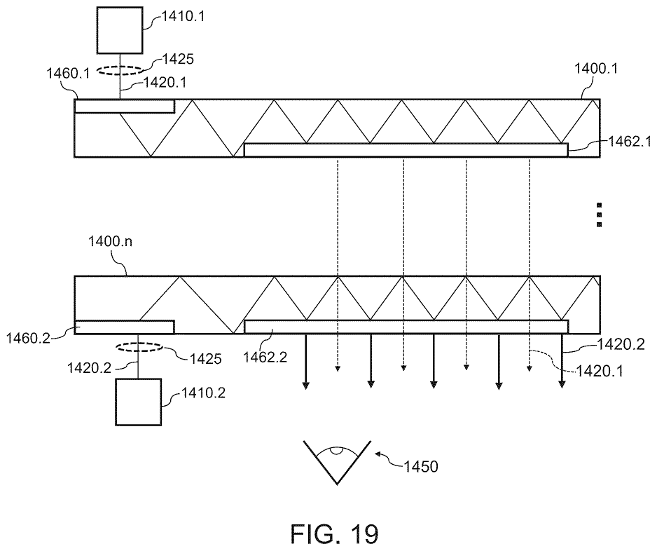

FIG. 19 depicts an example embodiment having a plurality of waveguides 1400.1, . . . 1400.n. Two waveguides 1400.1, . . . 1400.n are illustrated in FIG. 19 for purposes of illustration and discussion. However, those of ordinary skill in the art, using the disclosures provided herein, will understand that the system may include any number of waveguides 1400.1, . . . 1400.n without deviating from the scope of the present disclosure.

As illustrated, one or more first light sources 1410.1 may provide one or more first light signals 1420.1 to a first input coupler 1460.1 on a first waveguide 1400.1. The one or more light signals 1420.1 may propagate through at least a portion of the first waveguide 1400.1 (e.g., using internal reflection) and may exit the first waveguide 1400.1 at a first output coupler 1462.1. The one or more first light signals 1420.1 may be transmitted through the second waveguide 1400.n and may be provided to a user 1450 as a visual display.

One or more second electromagnetic radiation sources 1410.2 may provide one or more second light signals 1420.2 to a second input coupler 1460.2. The one or more second light signals 1420.2 may propagate through at least a portion of the second waveguide 1400.n (e.g., using internal reflection) and may exit the second waveguide 1400.n at a second output coupler 1462.2. The one or more second electromagnetic radiation signals 1420.2 may be provided to a user 1450 as a visual display.

FIG. 20 depicts an example coupler 1560 (e.g., input coupler or output coupler) that comprises a grating 1563 defined in the surface of an optical device 1502 (e.g., in the silicon carbide material of the optical device). The grating 1563 may be formed using a surface processing operation suitable for processing hard materials, such as silicon carbide. In some examples, the grating 1563 may be defined using emission of one or more lasers to remove or ablate material from the optical device 1502 to form the grating 1563. The grating 1563 may include a plurality of trenches 1565 and a plurality of mesas 1567. The trenches 1565, in some embodiments, may be laser-defined trenches 1565 in a silicon carbide optical device 1502.

Example aspects of the present disclosure are set forth below. Any of the below features or examples may be used in combination with any of the embodiments or features provided in the present disclosure.

One example aspect of the present disclosure is directed to a structure comprising a silicon carbide crystalline material. The silicon carbide crystalline material exhibits a change in an optical property when illuminated with polarized light along an axis generally perpendicular to a c-axis of the crystalline material. A thickness of the structure is at least about 10 mm.

In some implementations of the example structure, the optical property includes an absorption coefficient in wavelength range of about 420 nm to about 700 nm.

In some implementations of the example structure, the polarized light is linearly polarized light with a polarization direction that is generally perpendicular or generally parallel to the c-axis.

In some implementations of the example structure, the change in an optical property includes an increase in an absorption coefficient in a wavelength range from about 450 nm to about 495 nm in a first region in the silicon carbide crystalline material when illuminated with linearly polarized light along the axis generally perpendicular to the c-axis.

In some implementations of the example structure, the silicon carbide crystalline material does not exhibit an increase in absorption coefficient in a wavelength range from about 450 nm to about 495 nm in a second region in the silicon carbide crystalline material when illuminated with linearly polarized light along the axis generally perpendicular to the c-axis.

In some implementations of the example structure, the first region has a higher nitrogen dopant concentration relative to the second region.

In some implementations of the example structure, the silicon carbide crystalline material exhibits an increase in an absorption coefficient in a wavelength range from about 570 nm to about 590 nm in a first region in the silicon carbide crystalline material when illuminated with linearly polarized light along the axis generally perpendicular to the c-axis.

In some implementations of the example structure, the silicon carbide crystalline material does not exhibit an increase in the absorption coefficient in a wavelength range from about 570 nm to about 590 nm in a second region in the silicon carbide crystalline material when illuminated with linearly polarized light along the axis generally perpendicular to the c-axis.

In some implementations of the example structure, the second region is an electrically compensated region of the silicon carbide crystalline material.

In some implementations of the example structure, the first region has a higher p-type dopant concentration relative to the second region.

In some implementations of the example structure, the structure includes a window on at least one surface, the window having a surface roughness in a range of about 0.5 nm to about 100 nm.

In some implementations of the example structure, the window is on a surface associated with a c-plane of the silicon carbide crystalline material.

In some implementations of the example structure, the window is on a surface associated with a plane that is generally perpendicular to a c-plane of the silicon carbide crystalline material.

In some implementations of the example structure, the structure has an outer diameter in a range of about 100 mm to about 400 mm.

In some implementations of the example structure, the structure has a thickness along the c-axis in a range of about 10 mm to about 200 mm.

In some implementations of the example structure, the silicon carbide crystalline material includes one or more of 4H silicon carbide, 6H silicon carbide, semi-insulating silicon carbide, n-type silicon carbide, or p-type silicon carbide.

In some implementations of the example structure, the structure is a preform, workpiece, boule, or wafer.

In some implementations of the example structure, the structure is one or more of a lens, window, waveguide, Fresnel lens, prism, collimator, beam splitter, grating, polarizer, optical waveguide, filter, light multiplexer, optical amplifier, optical modulator, or refractor.

In some implementations of the example structure, the structure includes a first structure coupled to a second structure.

In some implementations of the example structure, the crystalline material includes an absorption coefficient along a c-axis of the crystalline material that is less than about 0.15 cm⁻¹ over a wavelength range from about 420 nm to about 700 nanometers.

In some implementations of the example structure, the crystalline material includes a notch absorption coefficient in a subset of a wavelength range from about 420 nm to about 700 nm.

In an aspect, the present disclosure provides an example structure. In some implementations, the example structure includes a first absorption coefficient that is less than about 0.15 cm⁻¹ over a wavelength range from about 420 nm to about 700 nm along a c-axis of the crystalline material. In some implementations, the silicon carbide crystalline material exhibits a change in a second absorption coefficient along an axis generally perpendicular to the c-axis when illuminated with polarized light along the axis generally perpendicular to the c-axis.

In some implementations of the example structure, the silicon carbide crystalline material exhibits a change in the second absorption coefficient when illuminated with linearly polarized light along the axis generally perpendicular to the c-axis.

In some implementations of the example structure, a polarization direction for the linearly polarized light is generally perpendicular or generally parallel to the c-axis.

In some implementations of the example structure, the silicon carbide crystalline material exhibits an increase in the second absorption coefficient in a wavelength range from about 450 nm to about 495 nm in a first region in the silicon carbide crystalline material when illuminated with linearly polarized light along an axis generally perpendicular to the c-axis.

In some implementations of the example structure, the silicon carbide crystalline material does not exhibit an increase in the second absorption coefficient in a wavelength range from about 450 nm to about 495 nm in a second region in the silicon carbide crystalline material when illuminated with linearly polarized light along the axis generally perpendicular to the c-axis.

In some implementations of the example structure, the first region has a higher nitrogen dopant concentration relative to the second region.

In some implementations of the example structure, the silicon carbide crystalline material exhibits an increase in the second absorption coefficient in a wavelength range from about 570 nm to about 590 nm in a first region in the silicon carbide crystalline material when illuminated with linearly polarized light along the axis generally perpendicular to the c-axis.

In some implementations of the example structure, the silicon carbide crystalline material does not exhibit an increase in the second absorption coefficient in a wavelength range from about 570 nm to about 590 nm in a second region in the silicon carbide crystalline material when illuminated with linearly polarized light along the axis generally perpendicular to the c-axis.

In some implementations of the example structure, the second region is an electrically compensated region of the silicon carbide crystalline material.

In some implementations of the example structure, the first region has a higher p-type dopant concentration relative to the second region.

In some implementations of the example structure, the structure includes a window on at least one surface, the window having a surface roughness in a range of about 0.5 nm to about 100 nm.

In some implementations of the example structure, the window is on a surface associated with a c-plane of the silicon carbide crystalline material.

In some implementations of the example structure, the window is on a surface associated with a plane that is generally perpendicular to a c-plane of the silicon carbide crystalline material.

In some implementations of the example structure, the structure has an outer diameter in a range of about 100 mm to about 400 mm.

In some implementations of the example structure, the structure has a thickness along the c-axis in a range of about 10 mm to about 200 mm.

In some implementations of the example structure, the silicon carbide crystalline material includes one or more of 4H silicon carbide, 6H silicon carbide, semi-insulating silicon carbide, n-type silicon carbide, or p-type silicon carbide.

In some implementations of the example structure, the structure is a workpiece, preform, wafer, or boule.

In some implementations of the example structure, the structure is one or more of a lens, a prism, a collimator, a beam splitter, a grating, a polarizer, an optical waveguide, a filter, or a refractor.

In some implementations of the example structure, the structure comprises a first structure coupled to a second structure.

In an aspect, the present disclosure provides an example structure. The structure includes a silicon carbide crystalline material. The structure has a first absorption coefficient less than about 0.15 cm⁻¹ over a wavelength range from 420 nm to about 700 nm along a c-axis of the crystalline material. The structure has a second absorption coefficient that is defined by a minimum value and a maximum value that are 0.15 cm⁻¹ apart over a wavelength range from about 420 nm to about 700 nm along a second axis generally perpendicular to the c-axis of the crystalline material. The structure has a thickness along the c-axis in a range of about 10 mm to about 200 mm.

In some implementations of the example structure, the structure has a generally cylindrical shape.

In some implementations of the example structure, the structure has a first surface associated with a silicon face and a second surface associated with a carbon face.

In some implementations of the example structure, the structure has at least one surface having a surface roughness in a range of about 0.5 nm to about 100 nm.

In some implementations of the example structure, the structure includes a window having a surface roughness in a range of about 0.5 nm to about 100 nm.

In some implementations of the example structure, the window is on a surface associated with a c-plane of the silicon carbide crystalline material.

In some implementations of the example structure, the window is on a surface that is generally perpendicular to a c-plane of the silicon carbide crystalline material.

In some implementations of the example structure, the structure includes a first surface and a second surface, wherein electromagnetic radiation having a wavelength range of from about 380 nm to about 1200 nm entering the first surface exits the second surface with a beam divergence of less than about 10 degrees.

In some implementations of the example structure, electromagnetic radiation having a wavelength range of from about 420 nm to about 700 nm entering the first surface exits the second surface with a beam divergence of less than about 10 degrees.

In some implementations of the example structure, the first surface and the second surface are generally parallel.

In some implementations of the example structure, the first surface and the second surface are not generally parallel.

In some implementations of the example structure, the silicon carbide crystalline material includes a first surface and a second surface, wherein electromagnetic radiation having a wavelength range of from about 380 nm to about 1200 nm entering the first surface is reflected from the second surface.

In some implementations of the example structure, electromagnetic radiation reflected from the second surface exits the first surface.

In some implementations of the example structure, electromagnetic radiation reflected from the second surface exits a third surface of the structure.

In some implementations of the example structure, at least one surface of the structure is a curved surface.

In some implementations of the example structure, at least one surface of the structure is a non-linear surface.

In some implementations of the example structure, the silicon carbide crystalline material exhibits a change in the absorption coefficient when illuminated with linearly polarized light along the axis generally perpendicular to the c-axis.

In some implementations of the example structure, a polarization direction for the linearly polarized light is generally perpendicular or generally parallel to the c-axis.

In some implementations of the example structure, the silicon carbide crystalline material exhibits an increase in the absorption coefficient in a wavelength range from about 450 nm to about 495 nm in a first region in the silicon carbide crystalline material when illuminated with linearly polarized light along the axis generally perpendicular to the c-axis.

In some implementations of the example structure, the silicon carbide crystalline material does not exhibit an increase in the absorption coefficient in a wavelength range from about 450 nm to about 495 nm in a second region in the silicon carbide crystalline material when illuminated with linearly polarized light along the axis generally perpendicular to the c-axis.

In some implementations of the example structure, the first region has a higher nitrogen dopant concentration relative to the second region.

In some implementations of the example structure, the silicon carbide crystalline material exhibits an increase in the absorption coefficient in a wavelength range from about 570 nm to about 590 nm in a first region in the silicon carbide crystalline material when illuminated with linearly polarized light along the axis generally perpendicular to the c-axis.

In some implementations of the example structure, the silicon carbide crystalline material does not exhibit an increase in the absorption coefficient in a wavelength range from about 570 nm to about 590 nm in a second region in the silicon carbide crystalline material when illuminated with linearly polarized light along the axis generally perpendicular to the c-axis.

In some implementations of the example structure, the second region is an electrically compensated region of the silicon carbide crystalline material.

In some implementations of the example structure, the first region has a higher p-type dopant concentration relative to the second region.

In some implementations of the example structure, the structure has an outer diameter in a range of about 100 mm to about 400 mm.

In some implementations of the example structure, the silicon carbide crystalline material includes one or more of 4H silicon carbide, 6H silicon carbide, semi-insulating silicon carbide, n-type silicon carbide, or p-type silicon carbide.

In some implementations of the example structure, the structure includes a first structure of silicon carbide crystalline material coupled to a second structure of silicon carbide crystalline material.

In some implementations of the example structure, the structure is a workpiece, boule, wafer, or preform.

In an aspect, the present disclosure provides a method of producing a silicon carbide structure. The method includes providing a silicon carbide crystalline material structure comprising a c-axis. The method includes measuring a change in at least one optical property of the crystalline material when illuminating the crystalline material with polarized light along an axis generally perpendicular to the c-axis. The method includes processing the silicon carbide crystalline material structure based at least in part on the change in the at least one optical property.

In some implementations of the example method, processing the silicon carbide crystalline material structure includes modifying a physical property of the silicon carbide crystalline material structure based at least in part on the change in the optical property.

In some implementations of the example method, the physical property includes one or more of: shape, thickness, diameter, edge count, or surface count.

In some implementations of the example method, processing the silicon carbide crystalline material structure includes sorting the silicon carbide crystalline material structure within a group of crystalline structures based at least in part on the change in the optical property.

In some implementations of the example method, processing the silicon carbide crystalline material structure includes inspecting the crystalline material structure for one or more defects based at least in part on the change in the optical property.

In some implementations of the example method, processing the crystalline material structure includes evaluating at least a portion of the crystalline material structure based at least in part on the change in the optical property.

In some implementations of the example method, the optical property includes an absorption coefficient in a wavelength range of about 420 nm to about 700 nm.

In some implementations of the example method, the polarized light is linearly polarized light with a polarization direction that is generally perpendicular or generally parallel to the c-axis.

In some implementations of the example method, the change in the optical property includes an increase in an absorption coefficient in a wavelength range from about 450 nm to about 495 nm in a first region in the silicon carbide crystalline material when illuminated with linearly polarized light along the axis generally perpendicular to the c-axis.

In some implementations of the example method, the silicon carbide crystalline material structure does not exhibit an increase in absorption coefficient in a wavelength range from about 450 nm to about 495 nm in a second region in the silicon carbide crystalline material structure when illuminated with linearly polarized light along the axis generally perpendicular to the c-axis.

In some implementations of the example method, the first region has a higher nitrogen dopant concentration relative to the second region.

In some implementations of the example method, the silicon carbide crystalline material structure exhibits an increase in an absorption coefficient in a wavelength range from about 570 nm to about 590 nm in a first region in the silicon carbide crystalline material structure when illuminated with linearly polarized light along the axis generally perpendicular to the c-axis.

In some implementations of the example method, the silicon carbide crystalline material structure does not exhibit an increase in the absorption coefficient in a wavelength range from about 570 nm to about 590 nm in a second region in the silicon carbide crystalline material structure when illuminated with linearly polarized light along the axis generally perpendicular to the c-axis.

In some implementations of the example method, the second region is an electrically compensated region of the silicon carbide crystalline material.

In some implementations of the example method, the first region has a higher p-type dopant concentration relative to the second region.

In some implementations of the example method, the crystalline material structure includes a window on at least one surface, the window having a surface roughness in a range of about 0.5 nm to about 100 nm.

In some implementations of the example method, the window is on a surface associated with a c-plane of the crystalline material structure.

In some implementations of the example method, the window is on a surface associated with a plane that is generally perpendicular to a c-plane of the crystalline material structure.

In some implementations of the example method, the crystalline material structure has an outer diameter in a range of about 100 mm to about 400 mm.

In some implementations of the example method, the crystalline material structure has a thickness along the c-axis in a range of about 10 mm to about 200 mm.

In some implementations of the example method, the silicon carbide crystalline material structure includes one or more of 4H silicon carbide, 6H silicon carbide, semi-insulating silicon carbide, n-type silicon carbide, or p-type silicon carbide.

In some implementations of the example method, the crystalline material structure is a preform, workpiece, boule, or wafer.

In some implementations of the example method, the crystalline material structure is one or more of a lens, a prism, a collimator, a beam splitter, a grating, a polarizer, an optical waveguide, or a refractor structure.

In some implementations of the example method, the crystalline material structure includes a first structure coupled to a second structure.

In some implementations of the example method, the crystalline material structure includes an absorption coefficient along the c-axis that is less than about 0.15 cm⁻¹ over a wavelength range from about 420 nm to about 700 nm.

In some implementations of the example method, the crystalline material structure includes a notch absorption coefficient in a subset of a wavelength range from about 420 nm to about 700 nm.

In an aspect, the present disclosure provides a method of producing a silicon carbide structure. The method includes providing a silicon carbide crystalline material structure comprising a c-axis. The method includes measuring a first optical property along a first axis through the crystalline material and measuring a second optical property along a second axis through the crystalline material, wherein the first axis is different from the second axis. The method includes processing the silicon carbide crystalline material structure based at least in part on the first optical property and the second optical property.

In some implementations of the example method, processing the silicon carbide crystalline material structure includes modifying a physical property of the crystalline material structure based at least in part on the optical property along the first axis and the optical property along the second axis.

In some implementations of the example method, the physical property includes one or more of: shape, thickness, diameter, edge count, or surface count.

In some implementations of the example method, processing the silicon carbide crystalline material structure includes sorting the crystalline material within a group of crystalline workpieces based at least in part on the optical property along the first axis and the optical property along the second axis.

In some implementations of the example method, processing the silicon carbide crystalline material structure includes inspecting a surface of the crystalline material for one or more defects based at least in part on the optical property along the first axis and the optical property along the second axis.

In some implementations of the example method, processing the silicon carbide crystalline material structure includes evaluating a dopant concentration of at least a portion of the crystalline material based at least in part on the optical property along the first axis and the optical property along the second axis.

In some implementations of the example method, the crystalline material includes a window on at least one surface, the window having a surface roughness in a range of about 0.5 nm to about 100 nm.

In some implementations of the example method, the window is on a surface associated with a c-plane of the crystalline material.

In some implementations of the example method, the window is on a surface associated with a plane that is generally perpendicular to a c-plane of the crystalline material.

In some implementations of the example method, the crystalline material structure has an outer diameter in a range of about 100 mm to about 400 mm.

In some implementations of the example method, the crystalline material structure has a thickness along the c-axis in a range of about 10 mm to about 200 mm.

In some implementations of the example method, the crystalline material structure includes one or more of 4H silicon carbide, 6H silicon carbide, semi-insulating silicon carbide, n-type silicon carbide, or p-type silicon carbide.

In some implementations of the example method, the crystalline material structure is a preform, workpiece, boule, or wafer.

In some implementations of the example method, the crystalline material structure is one or more of a lens, a prism, a collimator, a beam splitter, a grating, a polarizer, filter, an optical waveguide, Fresnel lens, or a refractor structure.

In some implementations of the example method, the crystalline material structure includes a first structure coupled to a second structure.

In some implementations of the example method, the first axis is along the c-axis and the second axis is generally perpendicular to the c-axis.

In some implementations of the example method, the first axis is along the c-axis and the second axis is non-perpendicular to the first axis.

In some implementations of the example method, the first axis is generally perpendicular to the c-axis and the second axis is non-perpendicular to the first axis.

In some implementations of the example method, the first axis and the second axis are non-perpendicular to the c-axis.

In some implementations of the example method, the first optical property is the same type of optical property as the second optical property.

In some implementations of the example method, the first optical property is a different type of optical property relative to the second optical property.

In some implementations of the example method, the first optical property and the second optical property comprise an absorption coefficient.

In some implementations of the example method, the crystalline material structure includes an absorption coefficient along a c-axis of the crystalline material that is less than about 0.15 cm⁻¹ over a wavelength range from about 420 nm to 700 nm.

In some implementations of the example method, the crystalline material structure includes a notch absorption coefficient in a subset of a wavelength range from about 420 nm to about 700 nm.

In some implementations of the example method, the first axis corresponds to a first dimension of a surface of the crystalline material structure and the second axis corresponds to a second dimension of the surface of the crystalline material structure.

In some implementations of the example method, the first axis and the second axis are associated with a crystal plane.

In some implementations of the example method, the first axis and the second axis are associated with an off-axis crystal plane.

In an aspect, the present disclosure provides an example optical device. In some implementations, the example optical device includes a waveguide of crystalline material, the crystalline material comprising silicon carbide. In some implementations, the example optical device includes a first input coupler on the waveguide, the first input coupler configured to input light for output as a first visual display. In some implementations, the example optical device includes a second input coupler on the waveguide, the second input coupler configured to input light for output as a second visual display, the second visual display being spatially separated from the first visual display.

In some implementations of the example optical device, the first input coupler is on a first major surface of the waveguide and the second input coupler is on a second major surface of the waveguide.

In some implementations of the example optical device, at least one of the first input coupler and the second input coupler is on an edge surface of the waveguide.

In some implementations of the example optical device, the optical device further comprises a divider.

In some implementations of the example optical device, at least one of first input coupler and the second input coupler is defined in the silicon carbide crystalline material of the waveguide.

In some implementations of the example optical device, at least one of first input coupler and the second input coupler includes a laser-defined structure.

In some implementations of the example optical device, at least one of first input coupler and the second input coupler includes a grating.

In some implementations of the example optical device, the waveguide includes a plurality of waveguides.

In some implementations of the example optical device, the waveguide has a first portion that is transparent to external light and a second portion that is opaque to external light, wherein the waveguide has a first output coupler in the first portion and a second output coupler in the second portion.

In some implementations of the example optical device, the optical device is a lens for an augmented reality or virtual reality headset.

In an aspect, the present disclosure provides an example optical device. In some implementations, the example optical device includes a waveguide of crystalline material, the crystalline material comprising silicon carbide, the waveguide comprising a plurality of couplers, the plurality of couplers comprising a plurality of input couplers and a plurality of output couplers. In some implementations, at least a coupler of the plurality of couplers is a structure defined in the silicon carbide crystalline material.

In some implementations of the example optical device, the at least one coupler includes a laser-defined structure.

In some implementations of the example optical device, the at least one coupler includes a grating.

In some implementations of the example optical device, the at least one coupler is on an edge surface of the waveguide.

In some implementations of the example optical device, the edge surface forms an acute angle with a major surface of the waveguide.

In some implementations of the example optical device, the edge surface forms an obtuse angle with a major surface of the waveguide.

In some implementations of the example optical device, the at least one coupler is on a major surface of the waveguide.

In some implementations of the example optical device, the at least one coupler includes an input coupler.

In some implementations of the example optical device, the at least one coupler includes an output coupler.

In an aspect, the present disclosure provides an example optical device. In some implementations, the example optical device includes a first waveguide comprising silicon carbide crystalline material. In some implementations, the example optical device includes a second waveguide comprising silicon carbide crystalline material. In some implementations, at least a portion of the first waveguide is generally parallel to the second waveguide. In some implementations, the first waveguide includes an output coupler configured to output light to be transmitted through the second waveguide.

In some implementations of the example optical device, the optical device further comprises a second output coupler on the second waveguide.

In some implementations of the example optical device, the optical device further comprises a first input coupler on the first waveguide and a second input coupler on the second waveguide.

In some implementations of the example optical device, the first waveguide includes a structure on the first waveguide that is opaque to external light.

In some implementations of the example optical device, the first waveguide and the second waveguide are transparent to external light.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A structure comprising a silicon carbide crystalline material,
wherein the silicon carbide crystalline material exhibits a change in an optical property when illuminated with polarized light along an axis generally perpendicular to a c-axis of the crystalline material;
wherein a thickness of the structure is at least about 10 mm.

2. The structure of claim 1, wherein the optical property comprises an absorption coefficient in wavelength range of about 420 nm to about 700 nm.

3. The structure of claim 1, wherein the polarized light is linearly polarized light with a polarization direction that is generally perpendicular or generally parallel to the c-axis.

4. The structure of claim 3, wherein the change in an optical property comprises an increase in an absorption coefficient in a wavelength range from about 450 nm to about 495 nm in a first region in the silicon carbide crystalline material when illuminated with linearly polarized light along the axis generally perpendicular to the c-axis.

5. The structure of claim 4, wherein the silicon carbide crystalline material does not exhibit an increase in absorption coefficient in a wavelength range from about 450 nm to about 495 nm in a second region in the silicon carbide crystalline material when illuminated with linearly polarized light along the axis generally perpendicular to the c-axis.

6. The structure of claim 5, wherein the first region has a higher nitrogen dopant concentration relative to the second region.

7. The structure of claim 3, wherein the silicon carbide crystalline material exhibits an increase in an absorption coefficient in a wavelength range from about 570 nm to about 590 nm in a first region in the silicon carbide crystalline material when illuminated with linearly polarized light along the axis generally perpendicular to the c-axis.

8. The structure of claim 7, wherein the silicon carbide crystalline material does not exhibit an increase in the absorption coefficient in a wavelength range from about 570 nm to about 590 nm in a second region in the silicon carbide crystalline material when illuminated with linearly polarized light along the axis generally perpendicular to the c-axis.

9. The structure of claim 8, wherein the first region has a higher p-type dopant concentration relative to the second region.

10. The structure of claim 1, wherein the structure has an outer diameter in a range of about 100 mm to about 400 mm.

11. The structure of claim 1, wherein the structure has a thickness along the c-axis in a range of about 10 mm to about 200 mm.

12. The structure of claim 1, wherein the silicon carbide crystalline material comprises one or more of 4H silicon carbide, 6H silicon carbide, semi-insulating silicon carbide, n-type silicon carbide, or p-type silicon carbide.

13. The structure of claim 1, wherein the structure comprises one or more of a lens, window, waveguide, Fresnel lens, prism, collimator, beam splitter, grating, polarizer, optical waveguide, filter, light multiplexer, optical amplifier, optical modulator, or refractor.

14. A method of producing a silicon carbide structure, comprising,
providing a silicon carbide crystalline material structure comprising a c-axis;
measuring at least one optical property of the crystalline material when illuminating the crystalline material with polarized light along an axis generally perpendicular to the c-axis; and
processing the silicon carbide crystalline material structure based at least in part on the at least one optical property.

15. The method of claim 14, wherein processing the silicon carbide crystalline material structure comprises:
modifying a physical property of the silicon carbide crystalline material structure based at least in part on the optical property, wherein the physical property comprises one or more of: shape, thickness, diameter, edge count, or surface count.

16. The method of claim 14, wherein processing the silicon carbide crystalline material structure comprises:
sorting the silicon carbide crystalline material structure within a group of crystalline structures based at least in part on the optical property.

17. The method of claim 14, wherein processing the silicon carbide crystalline material structure comprises:
inspecting the crystalline material structure for one or more defects based at least in part on the optical property.

18. The method of claim 14, wherein the optical property comprises an increase in an absorption coefficient in a wavelength range from about 450 nm to about 495 nm in a first region having a higher nitrogen dopant concentration relative to a second region.

19. An optical device, comprising:
a waveguide of crystalline material, the crystalline material comprising silicon carbide;
a first input coupler on the waveguide, the first input coupler configured to input light for output as a first visual display;
a second input coupler on the waveguide, the second input coupler configured to input light for output as a second visual display, the second visual display being spatially separated from the first visual display.

20. The optical device of claim 19, wherein the optical device is a lens for an augmented reality or virtual reality headset.
